(19) United States
(12) Patent Application Publication
(10) Pub. No.: US 2011/0008640 A1
(43) Pub. Date: Jan. 13, 2011

(54) DISPLAY DEVICE, PROCESS FOR PRODUCING THE DISPLAY DEVICE, AND SPUTTERING TARGET

(75) Inventors: Hiroshi Goto, Hyogo (JP); Akira Nanbu, Hyogo (JP); Junichi Nakai, Hyogo (JP); Hiroyuki Okuno, Hyogo (JP); Mototaka Ochi, Hyogo (JP); Aya Miki, Hyogo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Kobe Seiko Sho (kobe Steel Ltd.), Kobe-shi (JP)

(21) Appl. No.: 12/922,764

(22) PCT Filed: Mar. 31, 2009
(86) PCT No.: PCT/JP2009/056719

§ 371 Date: Sep. 15, 2010

(30) Foreign Application Priority Data
Mar. 31, 2008 (JP) 2008-093992
Apr. 24, 2008 (JP) 2008-114333
Nov. 19, 2008 (JP) 2008-296005

(51) Int. Cl. G02F 1/1343; C09K 19/00; C22F 1/04; C23C 14/14

(52) U.S. Cl. 428/551; 204/298.13

(57) ABSTRACT

Disclosed is a display device comprising an aluminum alloy film. In a wiring structure of a thin-film transistor substrate for use in display devices, the aluminum alloy film can realize direct contact between a thin film of an aluminum alloy and a transparent pixel electrode, can simultaneously realize low electric resistance and heat resistance, and can improve resistance to corrosion by an amine-based peeling liquid and an alkaline developing solution used in a thin-film transistor production process. In the display device, an oxide electroconductive film is in direct contact with an Al alloy film and at least a part of the Al alloy component is precipitated on the contact surface of the Al alloy film. The Al alloy film comprises at least one element (element X1) selected from the group consisting of Ni, Ag, Zn, and Co and at least one element (element X2) which, together with the element X1, can form an intermetallic compound. An intermetallic compound, which has a maximum diameter of not more than 150 nm and is represented by at least one of X1—X2 and Al—X1—X2, is formed in the Al alloy film.

### TECHNICAL FIELD

The present invention relates to a display device including an improved thin-film transistor substrate, and for use in a liquid crystal display, a semiconductor device, an optical component, or the like. More particularly, it relates to a novel display device including an Al alloy thin film as a wiring material and a sputtering target.

### BACKGROUND ART

Liquid crystal displays (LCDs) have been used for displays of cellular phones, mobile terminals, and PC monitors in small and medium sizes. Further, in recent years, an increase in size has been pursued, so that liquid crystal displays have been also used for more than 30-inch large-size televisions. The liquid crystal displays are classified into those of simple matrix type and those of active matrix type according to the driving method of pixels. Each liquid crystal display includes an array substrate and an opposing substrate, and a liquid crystal layer injected therebetween, and further resin films such as color filters and polarizing plates, backlights, and the like. The array substrate includes switching elements (TFTs: Thin-Film Transistors), and pixels, and further scanning lines and signal lines for transmitting electric signals to the pixels by making full use of a micromachining technology developed in connection with semiconductors. Incidentally, an active matrix type liquid crystal display device having thin-film transistors as switching elements can implement a high precision image quality, and hence it has been used for general purposes.

FIG. 1 is a schematic cross-sectional enlarged illustrative view showing a configuration of a typical liquid crystal panel to be applied to an active matrix type liquid crystal display device. The liquid crystal panel shown in FIG. 1 has a TFT array substrate 1, an opposing substrate 2 disposed opposite the TFT substrate, and a liquid crystal layer 3 disposed between the TFT substrate 1 and the opposing substrate 2, and functioning as an optical modulation layer. The TFT array substrate 1 includes a light shield film 9 disposed in a position opposite a thin-film transistor (TFT) 4 and a wiring part 6 disposed on an insulating glass substrate 1a.

Further, on the outsides of the insulating substrates forming the TFT substrate 1 and the opposing substrate 2, polarizing plates 10 are disposed, respectively. In addition, the opposing substrate 2 has an alignment film 11 for aligning liquid crystal molecules contained in the liquid crystal layer 3 in a prescribed orientation.

With the liquid crystal panel in such a configuration, by the electric field generated between the opposing substrate and an oxide electroconductive film 5 (transparent electroconductive film or transparent pixel electrode), the alignment direction of liquid crystal molecules in the liquid crystal layer 3 is controlled. Thus, the light passing through the liquid crystal layer 3 between the TFT array substrate 1 and the opposing substrate 2 is modulated. As a result, transmission of light passing through the opposing substrate 2 is controlled, so that an image is displayed.

Further, the TFT array is driven by a driver circuit 13 and a control circuit 14 through a TAB tape 12 led outside the TFT array. Incidentally, in FIG. 1, 15 represents a spacer; 16, a sealing material; 17, a protective film; 18, a diffusion film; 19, a prism sheet; 20, a light guide plate; 21, a reflector; 22 a backlight; 23, a holding frame; and 24, a printed substrate.

FIG. 2 is a schematic cross-sectional illustrative view showing a configuration of a thin-film transistor (TFT) to be applied to an array substrate for the display device as described above. As shown in FIG. 2, on the glass substrate 1a, a scanning line 25 is formed of an Al alloy thin film. Apart of the scanning line 25 functions as a gate electrode 26 for controlling ON/OFF of the thin-film transistors. Whereas, a signal line is formed of an aluminum thin film in such a manner as to cross with the scanning line 25 via a gate insulating film 27. A part of the signal line functions as a source electrode 28 of the TFT. Incidentally, this type is generally referred to as a bottom gate type.

In the pixel region on the gate insulating film 27, for example, the oxide electroconductive film 5 formed of an ITO film in which. SnO is included in In₂O₃ is disposed. The drain electrode 29 of the thin-film transistor formed of an Al alloy film is in direct contact with and is electrically connected to the oxide electroconductive film 5.

When a gate voltage is supplied to the gate electrode 26 via the scanning line 25 on the TFT substrate 1a in the foregoing configuration, the thin-film transistor is rendered in an ON state. Thus, the driving voltage previously supplied to the signal line is supplied from the source electrode 28 to the oxide electroconductive film 5 via the drain electrode 29. Then, when a driving voltage at a prescribed level is supplied to the oxide electroconductive film 5, the driving voltage is applied to the liquid crystal element between it and the opposing common electrode, so that liquid crystal operates. Incidentally, in the configuration shown in FIG. 1, there is shown a state in which source-drain electrodes and the oxide electroconductive film 5 are in direct contact with each other. However, there may be adopted a configuration in which the gate electrode is also in contact with and electrically connected to the oxide electroconductive film 5 at the terminal part.

For the wiring material for use in scanning lines and signal lines, heretofore, there have been generally used pure Al, Al alloys, or refractory metals. The reason for this is that the wiring material is required to have a low electric resistivity, a corrosion resistance, a heat resistance, and the like.

For a large size liquid crystal display, the wiring length is large, and the wiring resistance and the wiring capacity accordingly increase. Therefore, the time constant representing the response speed increases, so that the display quality tends to be degraded. On the other hand, an increase in wiring width results in an increase in aperture ratio of pixel or wiring capacity. Alternatively, an increase in wiring film thickness causes problems such as an increase in material cost and a reduction of yield. For these reasons, a wiring material with a low electric resistivity is preferred.

Whereas, in the step of forming a liquid crystal display, microprocessing and cleaning of wiring are repeatedly performed. Further, for use, long-term display quality reliability is demanded, which requires a high corrosion resistance.

As a still other problem, the wiring material receives heat history in the production steps of a liquid crystal display, and hence is demanded to have a heat resistance. The structure of the array substrate includes a thin-film lamination structure. After formation of wiring, around 350° C. heat is applied by CVD or a heat treatment. For example, the melting point of Al is 660° C. However, a glass substrate and a metal have different thermal expansion coefficients. Therefore, upon receiving heat history, the metal thin film (wiring material) and the glass substrate has a stress therebetween. This serves as a driving force, so that the metal element diffuses, causing plastic deformations such as hillocks or voids. When hillocks or voids are formed, the yield decreases. Therefore, the wiring material is required not to undergo plastic deformation at 350° C.

Further, as described above, in the TFT substrate, as the wiring material for gate wires, source-drain wires, and the like, pure Al or Al alloys such as Al—Nd (which may be hereinafter collectively referred to as Al type alloys) are used for general purposes because of the low electric resistance, ease of micromachining, and other reasons. Between the Al type alloy wires and the transparent pixel electrodes, there is generally provided a barrier metal layer including a refractory metal such as Mo, Cr, Ti, or W. The reason why the Al type alloy wire is thus connected via the barrier metal layer is as follows. When the Al type alloy wire is directly connected to the transparent pixel electrode, the connection resistance (contact resistance) increases, resulting in degradation of the display quality of the screen. Namely, Al forming the wire to be directly connected to the transparent pixel electrode is very susceptible to oxidation. Thus, by oxygen formed in the process of deposition of the liquid crystal display, oxygen to be added during deposition, or the like, an insulating layer of an Al oxide is formed at the interface between the Al type alloy wire and the transparent pixel electrode. Further, a transparent electroconductive film such as ITO forming the transparent pixel electrode is an electroconductive metal oxide. However, electric ohmic connection cannot be carried out due to the Al oxide layer formed in the foregoing manner.

However, in order to form the barrier metal layer, a deposition chamber for barrier metal formation must be additionally mounted in addition to a sputtering device for deposition necessary for the formation of the gate electrode and the source electrode, and further the drain electrode. With the advance of reduction of cost with the trend for the mass production of liquid crystal displays, the increase in manufacturing cost and the reduction of the productivity entailed by formation of the barrier metal layer have become impossible to disregard.

Under such circumstances, there have been proposed electrode materials and production processes which can omit the formation of the barrier metal layer, and enables direct connection of the Al type alloy wire to the transparent pixel electrode.

Up to now, we have proposed the following technologies: by using novel Al alloy wiring materials and wiring film formation technologies, direct contact of an Al alloy film to a pixel electrode is enabled, and the multilayer wiring structure used for pure Al or the like is converted into a monolayer structure, thereby to omit a barrier metal layer (which may be hereinafter referred to as direct contact) (see Patent Documents 1 and 2).

For example, the present applicant discloses in Patent Document 1 a technology of, by using not pure Al but a multinary Al alloy film as typified by an Al—Ni type alloy as a wire, omitting a barrier metal layer, and bringing the Al alloy film and the oxide electroconductive film (transparent pixel electrode) into direct contact with each other. With the technology of Patent Document 1, by allowing the Al alloy film to include Ni and the like, it is possible to reduce the contact resistance between the Al alloy film and the oxide electroconductive film.

Incidentally, the Patent Document 2 successfully provides a thin-film transistor substrate which not only has implemented direct contact but also combines a reduced electric resistivity and a heat resistance of the Al alloy film itself even when direct contact is accomplished with a relatively low process temperature. It is shown in various embodiments that the corrosion resistance to an alkali developing solution, the corrosion resistance to alkali cleaning after development, and the like can also be improved together. In Patent Document 2, it is the basis of the invention that as the elements to be added into Al, elements of group a and elements of group X are selected, thereby to form an Al alloy composition including Al-α-X. As the element of the group α, there is used at least one selected from Ni, Ag, Zn, Cu, and Ge. As the element of the group X, there is used at least one selected from Mg, Cr, Mn, Ru, R h, Pd, Ir, La, Ce, Pr, Gd, Tb, Eu, Ho, Er, Tm, Yb, Lu, and Dy. However, the present invention can be regarded as the one obtained by successfully further developing the invention of the Patent Document 2.

Whereas, Patent Document 1 discloses an Al alloy including, as an alloy component, at least one selected from the group consisting of Au, Ag, Zn, Cu, Ni, Sr, Ge, Sm, and Bi in an amount of 0.1 to 6 at %. When the one including the Al alloy is used for the Al type alloy wire, at least a part of these alloy components is present as an intermetallic compound or a concentrated layer at the interface between the Al type alloy wire and the transparent pixel electrode. As a result, even when a barrier metal layer is omitted, the contact resistance with the transparent pixel electrode can be reduced.

However, the heat resistant temperatures of the Al alloys containing Ni and the like described in the Patent Document 1 are all about 150 to 200° C., and are lower than the maximum temperature in the production step of the display device (particularly, a TFT substrate).

Incidentally, in recent years, the production temperature of the display device tends to be more and more reduced from the viewpoints of improvement of yield and improvement of productivity. However, even when the maximum temperature (deposition temperature of the silicon nitride film) in the production steps is reduced to 300° C., it exceeds the heat resistant temperature of each Al alloy described in the Patent Document 1.

On the other hand, when the maximum temperature (which is referred to as a “heat treatment temperature” in the present invention) in the production steps is reduced, unfavorably, the electric resistance of the Al type alloy wire is not reduced sufficiently. Under such circumstances, the present applicant discloses in Patent Document 2 an Al alloy showing a sufficiently low electric resistance even with a low heat treatment temperature while showing a favorable heat resistance.

Use of the Al alloy film for the thin-film transistor substrate enables omission of the barrier metal layer, and can ensure contact between the Al alloy film and the transparent pixel electrode including an electroconductive oxide film directly and surely without increasing the number of steps. Further, even when the Al alloy film is applied with a heat treatment temperature as low as, for example, about 100° C. or more and 300° C. or less, it is possible to achieve reduction of the electric resistance and an excellent heat resistance. Specifically, there is the following description: even when a heat treatment at a temperature as low as, for example 250° C. for 30 minutes is adopted, 7 μΩ·cm or less in terms of the electric resistivity of the Al alloy film can be achieved without causing defects such as hillocks.

### [Patent Document 1] JP-A-2004-214606

[Patent. Document 2] JP-A-2006-261636

### DISCLOSURE OF THE INVENTION

### Problems to be Solved by the Invention

By adding an element to an Al alloy, various functions not observable in pure Al are imparted. On the other hand, an increase in addition amount results in an increase in electric resistivity of the wire itself. For example, for the direct contact property, the excellent performance can be obtained by adding an element (Ni, Ag, Zn, or Co) of the X1 group specified in the present specification. However, addition of the alloy element causes an undesirable tendency of degradation of the electric resistivity or the corrosion resistance.

In the large-size TV use, a multilayer wiring structure of pure Al is used. However, in view of the case where pure Al is changed into some Al alloy with the wiring design held as it is, the Al alloy wire (assumed to be used in monolayer premised on direct contact) preferably acquires an electric resistivity equal to or larger than the wiring structure total electric resistance.

Whereas, it has been additionally found that the heat resistance is improved by addition of La, Nd, Gd, Dy, or the like. However, as compared with the elements of the X1 group, the element itself is higher in precipitation temperature in the Al matrix. This unfavorably further degrades the electric resistivity. Incidentally, degradation of electric resistivity at this step depends upon the addition amount. For this reason, the amount of the element to be added is preferably smaller.

Incidentally, in the production step of the array substrate, the substrate passes through a plurality of wet processes. However, addition of a nobler metal than Al causes a problem of galvanic corrosion, resulting in deterioration of the corrosion resistance. For example, in the photolithography step, an alkaline developing solution containing TMAH (tetramethylammoniumhydroxide) is used. However, in the case of a direct contact structure, the barrier metal layer is omitted, so that the Al alloy is exposed. Accordingly, the Al alloy becomes more susceptible to damages by the developing solution.

Other than this, in a cleaning step of peeling a photoresist (resin) formed in the photolithography step, water washing is continuously performed using an organic peeling liquid containing amines. However, mixing of amines and water results in an alkaline solution. This causes another problem that Al is corroded in a short time. Incidentally, before passing through the peeling cleaning step, the Al alloy has gone through a CVD step, and has received heat history. In the process of the heat history, the alloy components form an intermetallic compound in the Al matrix. However, there is a large potential difference between the intermetallic compound and Al. Therefore, at the instant when the amine of the peeling liquid comes in contact with water, alkali corrosion proceeds due to the galvanic corrosion. Thus, Al which is electrochemically base ionizes and dissolves, so that pit-like pitting corrosions (which may be hereinafter referred to as black spots) are formed.

The black spot may be recognized as a defect with the appearance inspection, and is desired to be eliminated as much as possible from the viewpoint of the corrosion resistance.

The technologies of Patent Documents 1 and 2 enable the direct contact, namely, direct connection between the Al alloy film and the transparent pixel electrode. On the other hand, in recent years, there has been pursued a study on the process temperature for producing a display device. From the viewpoints of the improvement of yield and the improvement of productivity, the process temperature tends to become lower. Progress of reduction in process temperature makes it difficult for precipitation of additional elements to progress sufficiently. As a result, the grain growth of the intermetallic compound is not enough. This causes problems such as increases in electric resistivity and contact resistance of the Al alloy itself. The intermetallic compound exerts a good effect on the electric connection with the transparent pixel electrode. However, there is a demand for the improvement in terms of material in order to allow sufficient formation of the intermetallic compound even under the trend toward lower process temperature.

The present invention was completed in view of such circumstances. It is an object of the present invention to provide a display device including an aluminum alloy film which has acquired a low electric resistivity and a low contact resistance with a transparent electroconductive film even after undergoing a low-temperature heat treatment (300° C. or less) in a direct contact material, and has been improved in corrosion resistance and heat resistance of the Al alloy by control of additional elements and intermetallic compounds.

### Means for Solving the Problems

The gist of the present invention will be shown below.

(1) A display device, including: an oxide electroconductive film and an Al alloy film being in direct contact with each other, at least a part of Al alloy components being precipitated and present on the contact surface of the Al alloy film,

wherein the Al alloy film includes at least one of elements X1 selected from the group consisting of Ni, Ag, Zn, and Co, and at least one of elements X2 capable of forming an intermetallic compound with the element X1, and the intermetallic compound represented by at least one of X1—X2 and Al—X1—X2 with a maximum diameter of 150 nm or less is formed.

Incidentally, an element X3 described later may be added. The X1—X2 and Al—X1—X2 in this case mean that they may include X1—X2—X3 and Al—X1—X2—X3.

Further, as the elements X2, as described later, mention may be made of Cu, Ge, Si, Mg, In, Sn, B, and the like. For example, when Ni is selected as the element X1, and Cu selected as the element X2, an Al—Ni—Cu intermetallic compound is formed in the Al matrix. When Ge is selected as the element X2, an Al—Ni—Ge intermetallic compound is formed in the Al matrix.

Incidentally, as described above, when an improvement of the heat resistance in the process step is further intended, mixing of one or more selected from La, Nd, Gd, Dy, and the like also corresponds to execution of the present invention.

(2) The display device according to the item (1), wherein the density of the intermetallic compound represented by at least one of X1—X2 and Al—X1—X2 with a maximum diameter of 150 nm or more is less than one compound/100 μm².
(3) The display device according to the item (1), wherein at least a part of the element X2 is precipitated into the Al matrix by a 300° C. or less heat treatment.
(4) The display device according to the item (3), wherein at least a part of the element X2 is precipitated into the Al matrix by a 150° C. or more and 230° C. or less heat treatment.
(5) The display device according to the item (4), wherein at least a part of the element X2 is precipitated into the Al matrix by a 200° C. or less heat treatment.
(6) The display device according to the item (1), wherein the total area of the intermetallic compounds of X1—X2 and Al—X1—X2 in the Al alloy film is 50% or more of the total area of all the intermetallic compounds.
(7) The display device according to any of the items (1) to (6), wherein in the Al alloy film, the element X1 is Ni, and the element X2 is at least one of Ge and Cu, and at least one intermetallic compound of Al—Ni—Ge and Al—Ni—Cu is formed with a 300° C. or less heat treatment.
(8) The display device according to the item (1), wherein the arithmetic mean roughness Ra of the contact surface of the Al alloy film is 2.2 nm or more and 20 nm or less.

Incidentally, the arithmetic mean roughness Ra in the present invention is based on JIS B0601 (JIS standard amended in 2001).

(9) The display device according to the item (8), wherein the Al alloy film includes the element X1 in a total amount of 0.05 to 2 at %.
(10) The display device according to the item (9), wherein the element X2 is at least one of Cu and Ge, and the Al alloy film includes at least one of Cu and Ge in a total amount of 0.1 to 2 at %.
(11) The display device according to the item (9) or (10), wherein the Al alloy film further includes at least one of rare earth elements in a total amount of 0.05 to 0.5 at %.
(12) The display device according to the item (11), wherein the rare earth element is at least one of elements selected from the group consisting of La, Nd, and Gd.
(13) A process for producing the display device according to the item (8), including:

bringing the Al alloy film into contact with an alkali solution before bringing the Al alloy film into direct contact with the oxide electroconductive film, and adjusting the arithmetic mean roughness Ra of the surface of the Al alloy film to 2.2 nm or more and 20 nm or less.

(14) The production process according to the item (13), wherein the alkali solution is an aqueous solution containing ammonia or alkanolamines.
(15) The production process according to the item (13), wherein adjustment of the arithmetic mean roughness Ra is performed in the peeling step of a resist film.
(16) The display device according to the item (1), wherein the Al alloy film includes Ni in an amount of 0.05 to 0.5 at % as the element X1, and Ge in an amount of 0.4 to 1.5 at % as the element X2, and further includes at least one element selected from a rare earth element group in a total amount of 0.05 to 0.3 at %, and the total content of Ni and Ge is 1.7 at % or less.
(17) The display device according to the item (16), wherein the rare earth element group includes Nd, Gd, La, Y, Ce, Pr, and Dy.
(18) The display device according to the item (16), wherein Co is included in an amount of 0.05 to 0.4 at % as the X1 element, and the total content of Ni, Ge, and Co is 1.7 at % or less.

Incidentally, the present invention also includes a display device wherein the Al alloy film is used for a thin-film transistor.

(19) A sputtering target including Ni in an amount of 0.05 to 0.5 at %, Ge in an amount of 0.4 to 1.5 at %, and at least one element selected from a rare earth element group in a total amount of 0.05 to 0.3 at %, the total content of Ni and Ge being 1.7 at % or less, and the balance being Al and inevitable impurities.
(20) The sputtering target according to the item (19), wherein the rare earth element group includes Nd, Gd, La, Y, Ce, Pr, and Dy.
(21) The sputtering target according to the item (19) or (20), further including Co in an amount of 0.05 to 0.4 at %, and the total content of Ni, Ge, and Co being 1.7 at % or less.

### ADVANTAGE OF THE INVENTION

In accordance with the present invention, it is possible to provide a display device including an aluminum alloy film which has acquired a low electric resistivity and a low contact resistance with a transparent electroconductive film even after undergoing a low-temperature heat treatment (300° C. or less) in a direct contact material, and has been improved in corrosion resistance and heat resistance of the Al alloy by control of additional elements and intermetallic compounds.

Further, by allowing the Al alloy film to include an element X2, the intermetallic compounds (precipitates) become finer, and the corrosion resistance is improved, which can prevent crater corrosion. Whereas, by controlling the arithmetic mean roughness Ra of the Al alloy film surface within a proper range, the contact resistance can be reduced.

Further, it is possible to provide an Al alloy film for a display device, which is configured such that the Al alloy film can be directly connected to the transparent pixel electrode (transparent electroconductive film, oxide electroconductive film) without a barrier metal layer interposed therebetween, and which exhibits a sufficiently low electric resistance even when applied with a relatively low heat treatment temperature (e.g., 250 to 300° C.), and is excellent in corrosion resistances (alkali developing solution resistance, peeling liquid resistance), and further is also excellent in heat resistance. Incidentally, the heat treatment temperature denotes the treatment temperature which is the highest temperature during the production steps (e.g., a production step of a TFT substrate) of the display device. In the production steps of a general display device, the heat treatment temperature means the heating temperature of the substrate during CVD deposition for formation of various thin films, the temperature of a heat treatment furnace for heat setting the protective film, or the like.

Whereas, when the Al alloy film of the present invention is applied to a display device, the barrier metal layer can be omitted. Therefore, use of the Al alloy film of the present invention can provide a display device excellent in productivity, low in cost, and high in performance.

### BRIEF DESCRIPTION OF THE DRAWINGS

FIG. 1 is a schematic cross-sectional enlarged illustrative view showing a configuration of a typical liquid crystal panel to be applied to an active matrix type liquid crystal display device;

FIG. 2 is a schematic cross-sectional illustrative view showing a configuration of a thin-film transistor (TFT) to be applied to an array substrate for a display device;

FIG. 3 shows a TEM observation image of Al—0.2Ni—0.35La;

FIG. 4 shows a TEM observation image of Al—1Ni—0.5Cu—0.3La;

FIG. 5 shows a TEM observation image of Al—0.5Ni—0.5Ge—0.3La;

FIG. 6 is a schematic cross-sectional enlarged illustrative view showing a configuration of a typical liquid crystal display to which an amorphous silicon TFT substrate is applied;

FIG. 7 is a schematic cross-sectional illustrative view showing a configuration of a TFT substrate in accordance with a first embodiment of the present invention;

FIG. 8 is an illustrative view showing step by step one example of the production step of the TFT substrate shown in FIG. 7;

FIG. 9 is an illustrative view showing step by step one example of the production step of the TFT substrate shown in FIG. 7;

FIG. 10 is an illustrative view showing step by step one example of the production step of the TFT substrate shown in FIG. 7;

FIG. 11 is an illustrative view showing step by step one example of the production step of the TFT substrate shown in FIG. 7;

FIG. 12 is an illustrative view showing step by step one example of the production step of the TFT substrate shown in FIG. 7;

FIG. 13 is an illustrative view showing step by step one example of the production step of the TFT substrate shown in FIG. 7;

FIG. 14 is an illustrative view showing step by step one example of the production step of the TFT substrate shown in FIG. 7;

FIG. 15 is an illustrative view showing step by step one example of the production step of the TFT substrate shown in FIG. 7;

FIG. 16 is a schematic cross-sectional illustrative view showing a configuration of a TFT substrate in accordance with a second embodiment of the present invention;

FIG. 17 is an illustrative view showing step by step one example of the production step of the TFT substrate shown in FIG. 16;

FIG. 18 is an illustrative view showing step by step one example of the production step of the TFT substrate shown in FIG. 16;

FIG. 19 is an illustrative view showing step by step one example of the production step of the TFT substrate shown in FIG. 16;

FIG. 20 is an illustrative view showing step by step one example of the production step of the TFT substrate shown in FIG. 16;

FIG. 21 is an illustrative view showing step by step one example of the production step of the TFT substrate shown in FIG. 16;

FIG. 22 is an illustrative view showing step by step one example of the production step of the TFT substrate shown in FIG. 16;

FIG. 23 is an illustrative view showing step by step one example of the production step of the TFT substrate shown in FIG. 16;

FIG. 24 is a view showing the size of the one regarded as a black spot and the intermetallic compound size at that moment; and

FIG. 25 is a view showing a Kelvin pattern (TEG pattern) used in measurement of the direct contact resistance between an Al alloy film and a transparent pixel electrode.

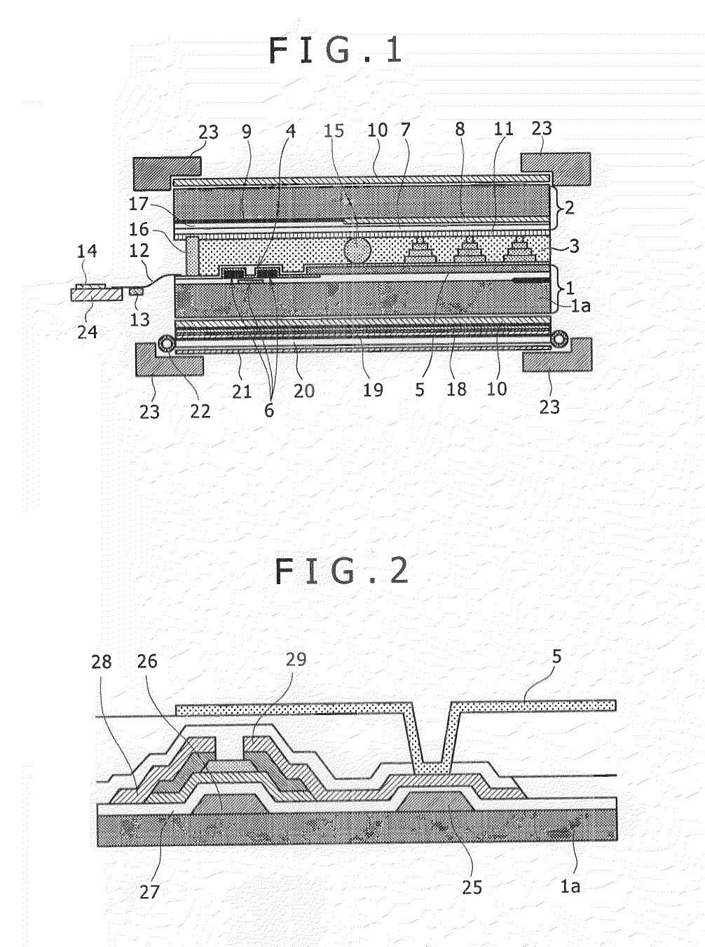

### DESCRIPTION OF REFERENCE NUMERALS AND SIGNS

1 TFT substrate (TFT array substrate)
2 Opposing substrate
3 Liquid crystal layer
4 Thin-film transistor (TFT)
5 Transparent pixel electrode (transparent electroconductive film, oxide electroconductive film)
6 Wiring part
7 Common electrode
8 Color filter
9 Light shield film
10, 10a, 10b polarizing plate
11 Alignment film
12 TAB tape
13 Driver circuit
14 Control circuit
15 Spacer
16 Sealing material
17 Protective film
18 Diffusion plate
19 Prism sheet
20 Light guide plate
21 Reflector plate
22 Backlight
23 Holding frame
24 Printed substrate
25 Scanning line
26 Gate electrode
27 Gate insulating film
28 Source electrode
29 Drain electrode
30 Protective film (silicon nitride film)
31 Photoresist
32 Contact hole
33 Amorphous silicon channel film (active semiconductor film)
34 Signal line
52, 53 Barrier metal layer
55 Non-doping hydrogenated amorphous silicon film (a-Si—H)
56 n⁺ type hydrogenated amorphous silicon film (n⁺ a-Si—H)

### BEST MODE FOR CARRYING OUT THE INVENTION

In the present invention, a technology of overcoming the foregoing problems was completed from the viewpoint of material design.

First, as a technical means for promoting the formation of intermetallic compounds, first, the elements of the X1 group were conceived as elements capable of exhibiting a low electric resistivity and a low contact resistance with a transparent electroconductive film even after undergoing a low-temperature heat treatment. The study on the direct contact technology continued by the present inventors indicates as follows: by allowing the Al alloy film to include the elements X1 (Ni, Ag, Zn, and Co), an intermetallic compound including the elements X1 is precipitated at the interface between the Al alloy film and the oxide electroconductive film (i.e., the contact surface of the Al alloy film), which can reduce the contact resistance.

Secondly, in the Al matrix, an element which is precipitated at a lower temperature than that for the X1 element (early from the initial stage of temperature rising from the viewpoint of the temperature rising process) is added. Thus, the element X2 group precipitated earlier in terms of time is allowed to function as the precipitation nucleus of the element X1 group. Under this idea, the elements of the X2 group were examined. As a result, the following was found. As the elements of the X2 group, Cu, Ge, Si, Mg, In, Sn, B, and the like were conceived. Inclusion of the X2 group element in the Al alloy film can refine the precipitate (intermetallic compound including the elements X1 and X2). This can effectively prevent crater corrosion.

Incidentally, the mechanism for refining of the precipitate (intermetallic compound) is presumed as follows. First, an element X2 is precipitated as a fine nucleus at a low temperature, and an element X1 is precipitated therearound; thus, a fine intermetallic compound (X1—X2 or Al—X1—X2) is formed. Then, the intermetallic compound serving as the starting point of corrosion is refined, and is dispersed finely. As a result, the corrosion resistance is improved. Incidentally, the present invention is not limited to the presumed mechanism.

Further, an experiment was carried out under the following assumption: in order for the Al alloy film to have a heat resistance such as hillock preventive property necessary in the process step, La, Nd, Gd, or Dy (which may be described as an X3 group element or simply an X3 element in this specification) is added in a small amount.

The element X1 is at least one selected from the group consisting of Ni, Ag, Zn, and Co, and is preferably Ni. In order for the contact resistance reducing effect to be sufficiently exerted, the total content of the elements X1 is preferably 0.05 at % or more, more preferably 0.08 at % or more, furthermore preferably 0.1 at % or more, and still more preferably 0.2 at % or more. However, when the total content of the elements X1 is excessive, the precipitate (intermetallic compound) becomes coarse (see Examples described later). Thus, the total content of the elements X1 is preferably 2 at % or less, and more preferably 1.5 at % or less.

The element selected as the X2 group has no particular restriction so long as it can form an intermetallic compound including X1. However, preferred is an element which starts to be precipitated at a temperature as low as 300° C. or less, preferably 270° C. or less, further preferably 250° C. or less, still further preferably 230° C. or less, and still furthermore preferably 200° C. or less in the temperature rising process. The element X2 is preferably at least one selected from the group consisting of Cu, Ge, Si, Mg, In, Sn, and B, and more preferably Cu and/or Ge. In order for the precipitate (intermetallic compound) refining effect to be sufficiently exerted, the total content of the elements X2 is preferably 0.1 at % or more, more preferably 0.2 at % or more, and further preferably 0.5 at % or more. However, when the total content of the elements X2 is excessive, the intermetallic compound becomes coarse. Thus, the total content of the elements X1 is preferably 2 at % or less, and more preferably 1.5 at % or less. When Cu is selected as the element of the X2 group, a 10 to 30 nm diameter fine intermetallic compound of Al—Cu or Al—Cu—X3 is formed in the grain boundary at a temperature of, for example, 150 to 230° C. Whereas, also when Ge is selected, similarly, a fine intermetallic compound of Ge—X3 is formed at a temperature of, for example, 150 to 230° C. Further, the temperature is risen, and at from the vicinity of 200° C., the element of the X1 group also starts to be precipitated. However, at this step, precipitation proceeds with the intermetallic compounds including the elements of the X2 group as nuclei.

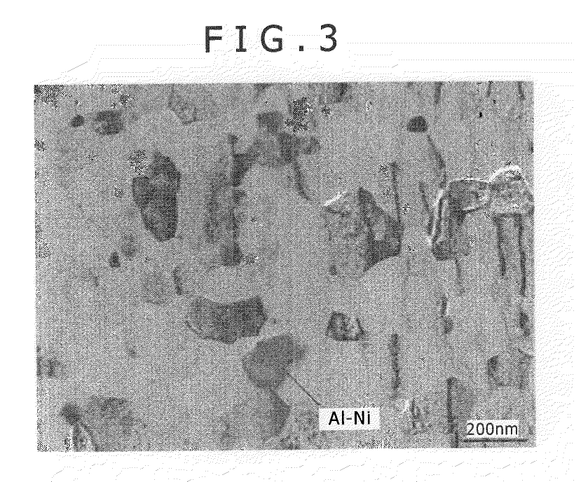

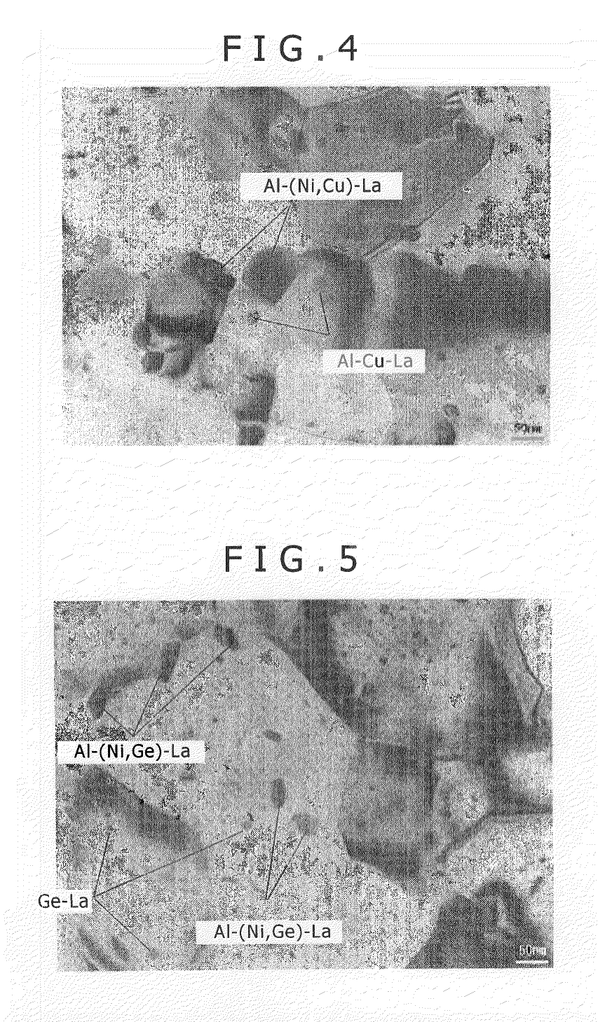

When no element of the X2 group is included (the element of the X3 group may be included), for example, with Al—Ni—La, intermetallic compounds such as Al₃Ni and Al₄La (or Al₃La) are formed. However, the intermetallic compounds of Al₃Ni include those with a diameter of 150 to 300 nm (FIG. 3: TEM observation image). However, upon addition of the element (e.g., Cu) of the X2 group, before recrystallization of Al proceeds, the element of the X2 group is finely dispersed in the grain boundary of Al, so that intermetallic compounds are formed in high density. By using the intermetallic compounds as nuclei, about 20 to 100 nm diameter fine intermetallic compounds of Al—Ni—Cu and Al—Ni—Cu—La are uniformly dispersed and formed in the film (FIG. 4: TEM observation image). When the X2 element group is added, precipitation thereof at low temperatures proceeds quickly, and a large number of precipitates are finely dispersed in the Al matrix. Therefore, the finely dispersed nuclei respectively gather X1 elements such as Ni, so that growth as intermetallic compounds proceeds. This results in that individual intermetallic compounds are small in size (large in number).

As a result, the intermetallic compounds are dispersed and formed uniformly in high density at low temperatures, so that the contact resistance is stabilized. Therefore, even when the amount of X1 to be added is low, the direct contact property is relatively stabilized, and hence a lower resistance can also be implemented.

Similarly, also when the X2 element is Ge, fine intermetallic compounds of Al—Ni—Ge and Al—Ni—Ge—La are quickly dispersed and formed (FIG. 5: TEM observation), which has an effect on stabilization of the direct contact property. Whereas, when the present invention is practiced with a combination of Co as the X1 element and Ge as the X2 element, intermetallic compounds of Al—Co—Ge and Al—Co—Ge—La are formed. Also when Ag or Zn is selected as the X1 element, the same phenomenon is observed.

The precipitate (intermetallic compound represented by X1—X2 or Al—X1—X2) formed has a maximum diameter of 150 nm or less, preferably 140 nm or less, and more preferably 130 nm or less in order to improve the corrosion resistance of the Al alloy film. Further, the density of intermetallic compounds with a maximum diameter of 150 nm or more is preferably less than one compound per 100 μm². Such intermetallic compounds can be formed in the following manner An Al alloy film including a proper amount of elements X1 and X2 is deposited by sputtering or the like, and then, is heat-treated at a temperature of about 300° C. for about 30 minutes. The maximum diameter of the intermetallic compounds is measured by means of a transmission electron microscope (TEM, magnification 150000 times). Incidentally, the intermetallic compound morphology is observed by a cross-section TEM or a reflection SEM. The mean value of the major axis length and the minor axis length of the intermetallic compound diameter is referred to as the maximum diameter of the intermetallic compound. In Examples described later, a total of three 1200 μm×1600 μm measurement visual fields were measured. Thus, a sample in which the maximum value of the intermetallic compound maximum diameter in each measurement visual field satisfies 150 nm or less is rated as “acceptable”.

The total area of the intermetallic compounds represented by X1—X2 and Al—X1—X2 in the Al alloy film is preferably 50% or more of the total area of all the intermetallic compounds.

In order to improve the heat resistance, and to prevent hillock formation due to a heat treatment or the like, the Al alloy film may include rare earth elements (preferably at least one selected from the group consisting of La, Nd, and Gd). In order for the heat resistance improving effect to be sufficiently exerted, the total content of the rare earth elements is preferably 0.05 at % or more, more preferably 0.1 at % or more, and further preferably 0.2 at % or more. However, when the total content of the rare earth elements is excessive, the resistance of the Al alloy film itself increases. Thus, the total content of rare earth elements is preferably 0.5 at % or less, and more preferably 0.4 at % or less.

A study by the present inventors revealed the following. The Al alloy film is brought in contact with an alkali solution before it is brought in direct contact with the oxide electroconductive film. Accordingly, the arithmetic mean roughness Ra of the surface is adjusted to 2.2 nm or more (preferably 3 nm or more, and more preferably 5 nm or more), and 20 nm or less (preferably 18 nm or less, and more preferably 15 nm or less). As a result, the contact resistance can be reduced. The arithmetic mean roughness Ra in the present invention is based on JIS B0601: 2001 (JIS standard amended in 2001). The reference length for Ra evaluation is 0.08 mm, and the evaluation length is 0.4 mm.

A previous treatment of the Al alloy film with an alkali solution causes the following: (1) the oxide present on the surface is removed; and (2) at least a part of the Al alloy components is exposed at the surface, resulting in an increase in contact area with the oxide electroconductive film. This can conceivably reduce the contact resistance.

As shown in Example 2-1 described below, in either case where Ra of the Al alloy film surface is too small or too large, the contact resistance is not sufficiently reduced. First, the reason why too small Ra results in an increase in contact resistance is considered as follows: dissolution of the oxide film on the intermetallic compound surface present on the Al alloy film surface is insufficient. On the other hand, even when Ra is too large, the Al alloy film itself is excessively corroded. Accordingly, the contact between the Al alloy film and the oxide electroconductive film deviates from the normal range. This conceivably results in an increase in contact resistance.

It is a preferred embodiment of the present invention that preferably, any of gate electrodes, source electrodes, and drain electrodes, and more preferably all the electrodes of the display device are formed of the Al alloy film.

As described above, one feature of the display device of the present invention is that Ra is adjusted within a proper range. A process for producing the display device of the present invention is characterized in that the Al alloy film is brought in contact with an alkali solution to adjust Ra within a proper range. In order to control Ra within a proper range, for example, as described below, it is essential only that in an alkali aqueous solution, the Al alloy film is immersed for about several tens of seconds to several minutes.

Specifically, it is essential only that the immersion time is properly adjusted according to the composition of the Al alloy film used, pH of the alkali aqueous solution, and the like. This is because the intermetallic compounds vary in size and density according to the composition of the Al alloy film used. For example, it is preferable that the pH of the alkali solution is changed with a content of element X1 (typically Ni or the like) of roughly in the vicinity of 1 at % as the boundary. In the case of X1<about 1 at %, contact with an alkali solution having a pH of 9.5 or more is preferable; and in the case of X1≧about 1 at %, contact with an alkali solution having a pH of 8.0 or more is preferable. Further, as shown in Examples described below, an immersion time of about 40 seconds can also control Ra to a prescribed level. With the production process of the present invention, the alkali solution is preferably an aqueous solution containing ammonia or alkanolamines (particularly, ethanolamines).

With the production process of the present invention, it is also acceptable that in the peeling step of the resist film for wiring patterning, Ra is adjusted within a proper range. Namely, for patterning of the display device, in the peeling step of the resist film (step of removal of the resist film with a peeling liquid and subsequent water washing), the Al alloy film comes in contact with an alkali solution. Therefore, in this step Ra may be adjusted together with resist peeling.

Further, the present inventors conducted a close study in order to implement an Al alloy film which can be sufficiently reduced in electric resistance even when the heat treatment temperature is low, and can be sufficiently reduced in contact resistance also when it is in direct contact with the transparent pixel electrode with a barrier metal layer omitted, and further is excellent in resistance (corrosion resistance) to a chemical liquid (alkali developing solution or peeling liquid) for use in the production process of the display device, and also in heat resistance. As a result, under a conception that an Al alloy film including a relatively small amount of Ni, Ge, and rare earth elements as essential elements is preferable, a specific process thereof was found. Below, the reason why the elements are selected in the present invention and the reason why the contents thereof are specified will be described in details.

The Al alloy film of the present invention preferably includes Ni in an amount of 0.05 to 0.5 at %. By thus allowing the Al alloy film to include a relatively small amount of Ni, the contact resistance can be suppressed low.

The mechanism can be considered as follows. Namely, when the Al alloy film is allowed to include Ni therein as an alloy component, even a low heat treatment temperature facilitates formation of an electroconductive Ni-containing intermetallic compound or Ni-containing concentrated layer at the interface between the Al alloy film and the transparent pixel electrode. This can prevent the formation of an insulating layer including an Al oxide at the interface. Thus, between the Al alloy film and the transparent pixel electrode (e.g., ITO), most of a contact current flows through the Ni-containing intermetallic compound or Ni-containing concentrated layer. This can conceivably suppress the contact resistance low.

Whereas, Ni is also effective for sufficiently reducing the electric resistance when a relatively low heat treatment temperature is applied thereto.

In order for the advantageous effects by Ni to be sufficiently exerted, the Ni content is preferably set at 0.05 at % or more. The Ni content is preferably 0.08 at % or more, more preferably 0.1 at % or more, and further preferably 0.2 at % or more. However, when the Ni content is excessive, the corrosion resistance tends to be reduced. By setting the Ni content low, it is possible for the film to also have excellent corrosion resistance. From such a viewpoint, in the present invention, the upper limit of the Ni content is preferably set at 0.5 at %, and more preferably 0.4 at % or less.

Whereas, when Ge is included therein together with Ni, the contact resistance can also be sufficiently reduced. The mechanism can be considered as follows. Even when a heat treatment is performed at a low temperature, intermetallic compounds including Ge and Ni are formed. Through the intermetallic compounds, a contact current flows between the Al alloy film and the transparent pixel electrode (e.g., ITO). As a result, the contact resistance can be reduced.

Whereas, also from the viewpoint of more enhancing the resistance to a peeling liquid for use in peeling of a photosensitive resin as the corrosion resistance, it is effective that Ge is included therein.

In order for the advantageous effects by Ge to be sufficiently exerted, the Ge content is preferably set at 0.4 at % or more. The Ge content is preferably 0.5 at % or more. However, in the case of an excessive Ge content, when a relatively low heat treatment temperature is applied, the electric resistance cannot be reduced sufficiently, and the contact resistance even tends to be unable to be reduced. Further, the corrosion resistance also tends to be rather reduced. Therefore, the Ge content is preferably set at 1.5 at % or less, and more preferably 1.2 at % or less.

In the present invention, particularly, from the viewpoint of sufficiently reducing the electric resistance even when a relatively low heat treatment temperature is applied, the total content of Ni and Ge is preferably controlled at 1.7 at % or less. The total content is preferably 1.5 at % or less, and more preferably 1.0 at % or less.

In the present invention, in order to enhance the heat resistance and the corrosion resistance, it is preferable that at least one element selected from the rare earth element group (preferably, Nd, Gd, La, Y, Ce, Pr, Dy) is also included therein.

On the substrate including the Al alloy film formed thereon, thereafter, a silicon nitride film (protective film) is deposited with a CVD process or the like. However, at this step, a high-temperature heat applied to the Al alloy film causes a difference in thermal expansion between it and the substrate, presumably resulting in formation of hillocks (bump-like projections). However, inclusion of the rare earth elements can inhibit formation of hillocks. Further, inclusion of the rare earth elements can also improve the corrosion resistance.

As described above, in order to ensure the heat resistance and to enhance the corrosion resistance, the Al alloy film is allowed to include at least one element selected from the rare earth element group (preferably Nd, Gd, La, Y, Ce, Pr, Dy) in a total content of preferably 0.05 at % or more, and more preferably 0.1 at % or more. However, when the rare earth element content is excessive, the electric resistance of the Al alloy film itself after a heat treatment tends to increase. Thus, the total content of the rare earth elements is preferably set at 0.3 at % or less (preferably 0.2 at % or less).

Incidentally, the rare earth elements herein referred to mean an element group including lanthanoid elements (in the periodic table, a total of 15 elements from La with an atomic number of 57 to Lu with an atomic number of 71), and in addition, Sc (scandium) and Y (yttrium)).

The Al alloy film preferably includes Ni, Ge, and rare earth elements in the specified contents, and the balance being Al and inevitable impurities. However, further, in order to reduce the contact resistance, Co can be included therein.

The mechanism in which Co addition reduces the contact resistance can be considered as follows. Namely, when the Al alloy film is allowed to include Co therein as an alloy component, even a low heat treatment temperature facilitates formation of an electroconductive Co-containing intermetallic compound or Co-containing concentrated layer at the interface between the Al alloy film and the transparent pixel electrode. This can prevent formation of an insulating layer including an Al oxide at the interface. Thus, between the Al alloy film and the transparent pixel electrode (e.g., ITO), most of a contact current flows through the Co-containing intermetallic compound or Co-containing concentrated layer. This can conceivably suppress the contact resistance low.

In order to implement a low contact resistance and corrosion resistance improvement by Co described above, the Co content is preferably set at 0.05 at % or more. The Co content is more preferably 0.1 at % or more. However, when the Co content is excessive, the contact resistance is rather reduced, and the corrosion resistance tends to be reduced. Thus, the Co content is preferably set at 0.4 at % or less.

Whereas, also when Co is included therein, particularly, from the viewpoint of sufficiently reducing the electric resistance even when a relatively low heat treatment temperature is applied, the total content of Ni, Ge, and Co is preferably controlled at 1.7 at % or less. The total content is more preferably 1.5 at % or less, and further preferably 1.0 at % or less.

The Al alloy film is desirably formed using a sputtering target (which may be hereinafter referred to as a “target”) with a sputtering process. This is because it is possible to readily form a thin film superior in film in-plane uniformity of components and film thickness to thin films formed with an ion plating process, an electron beam deposition process, or a vacuum deposition process.

Further, in order to form the Al alloy film with the sputtering process, as the target, there is used an Al alloy sputtering target which includes Ni in an amount of 0.05 (preferably 0.08) to 0.5 at %, Ge in an amount of 0.4 to 1.5 at %, and at least one element selected from rare earth element group (preferably, Nd, Gd, La, Y, Ce, Pr, Dy) in a total amount of 0.05 to 0.3 at %, and includes Ni and Ge in a total amount of 1.7 at % or less, with the balance being Al and inevitable impurities, and has the same composition as that of a desirable Al alloy film. This can form an Al alloy film with desired components/composition without causing composition deviation, and hence is desirable.

As the sputtering target, the one further including Co in an amount of 0.05 to 0.4 at % (provided that the total amount of Ni, Ge, and Co is 1.7 at % or less) may be used according to the component composition of the Al alloy film to be deposited.

As for the shape of the target, there are included those processed in a given shape (such as rectangular plate form, circular plate form, or doughnut plate form) according to the shape and structure of the sputtering apparatus.

As the manufacturing method of the target, mention may be made of a method in which an ingot including an Al-base alloy is manufactured with a dissolution casting process, a powder sintering process, or a spray forming process for obtaining the target; and a method in which a preform including an Al-base alloy (intermediate before obtaining the final dense body) is manufactured, and then, the preform is densified by a densification means for obtaining the target.

The present invention also includes a display device in which the Al alloy film is used for a thin-film transistor. As embodiments thereof, mention may be made of: the one in which the Al alloy film is used for source electrodes and/or drain electrodes of a thin-film transistor and signal lines, and drain electrodes are directly connected to a transparent electroconductive film; and/or the one in which the Al alloy film is used for gate electrodes and scanning lines.

Further, the one in which the gate electrodes and scanning lines, and the source electrodes and/or drain electrodes and signal lines are the Al alloy films with the same composition is included as an embodiment.

As the transparent pixel electrode of the present invention, indium tin oxide (ITO) or indium zinc oxide (IZO) is preferable.

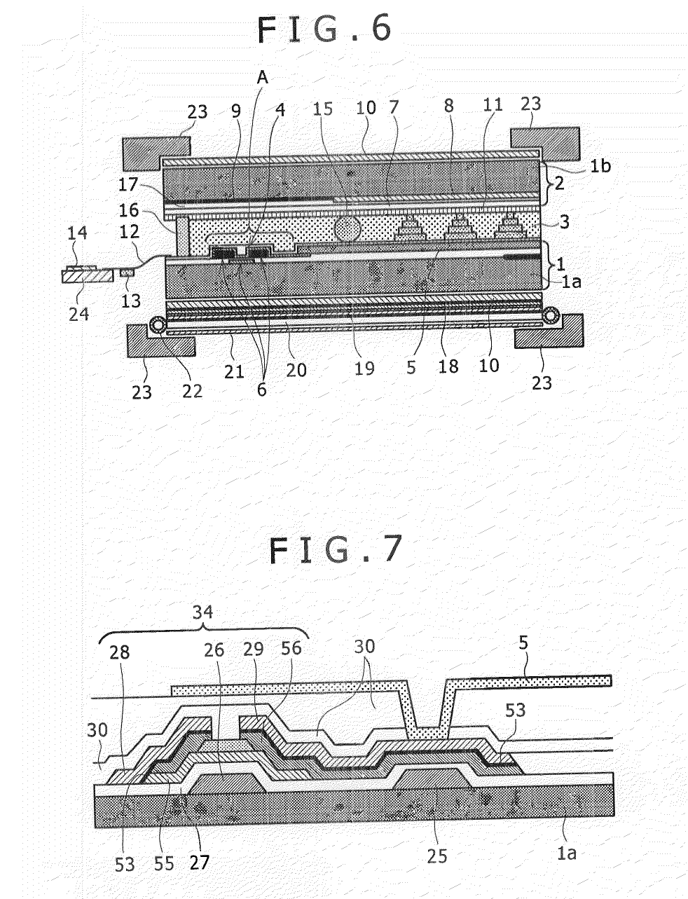

Below, with reference to the accompanying drawings, a description will be given to preferred embodiments of a display device in accordance with the present invention. Below, a liquid crystal display device including an amorphous silicon TFT substrate or a polysilicon TFT substrate (e.g., FIG. 6, the details of which will be described later) will be typically taken, and described. However, the present invention is not limited thereto.

### First Embodiment

By reference to FIG. 7, an embodiment of an amorphous silicon TFT substrate will be described in details.

FIG. 7 is an essential part enlarged view of A in FIG. 6 (one example of the display device in accordance with the present invention) described above, and a schematic cross-sectional illustrative view for illustrating a preferred embodiment of a TFT substrate (bottom gate type) of a display device in accordance with the present invention.

In this embodiment, as source-drain electrode/signal line (34) and gate electrode/scanning line (25, 26), Al alloy films are used. In the conventional TFT substrate, on the scanning line 25, on the gate electrode 26, and on or under the signal line 34 (source electrode 28 and drain electrode 29), barrier metal layers are formed, respectively. In contrast, in the TFT substrate of this embodiment, the barrier metal layers can be omitted.

Namely, in accordance with this embodiment, the Al alloy film for use in the drain electrode 29 of the TFT can be directly connected to a transparent pixel electrode 5 without the barrier metal layers interposed therebetween. Even in such an embodiment, favorable TFT characteristics comparable to, or greater than those of the conventional TFT substrate can be implemented.

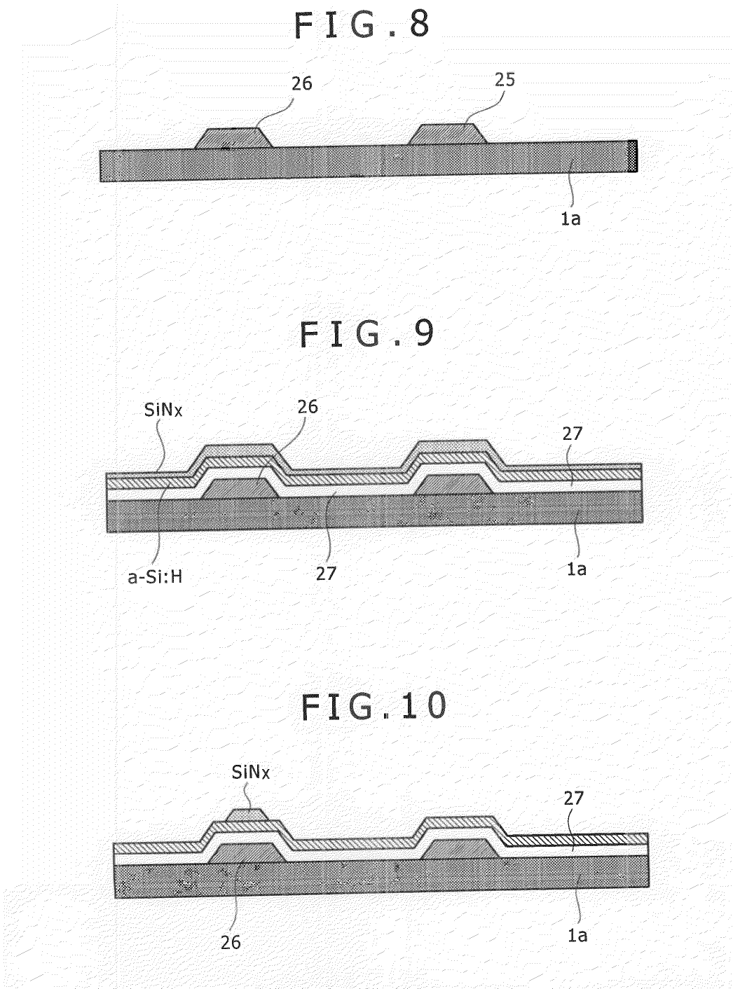

Then, with reference to FIGS. 8 to 15, a description will be given to one example of a manufacturing method of an amorphous silicon TFT substrate in accordance with the present invention shown in FIG. 7. The thin-film transistor is an amorphous silicon TFT using a hydrogenated amorphous silicon as the semiconductor layer. In FIGS. 8 through 15, the same reference numerals and signs as those in FIG. 7 are given.

First, on a glass substrate (transparent substrate) 1a, an Al alloy film is stacked with a thickness of about 200 nm by using a sputtering process. The deposition temperature of sputtering was set at 150° C. By patterning the Al alloy film, the gate electrode 26 and the scanning line 25 are formed (see FIG. 8). At this step, in FIG. 9 described later, the outer edge of the Al alloy film forming the gate electrode 26 and the scanning line 25 is desirably etched in the form of an about 30° to 40° taper so as to improve the coverage of the gate insulating film 27.

Then, as shown in FIG. 9, with a process such as a plasma CVD process, a gate insulating film 27 is formed of a silicon oxide film (SiOx) with a thickness of about 300 nm. The deposition temperature of the plasma CVD process was set at about 350° C. Subsequently, with a process such as a plasma CVD process, on the gate insulating film 27, a hydrogenated amorphous silicon film (αSi—H) with a thickness of about 50 nm and a silicon nitride film (SiNx) with a thickness of about 300 nm are deposited.

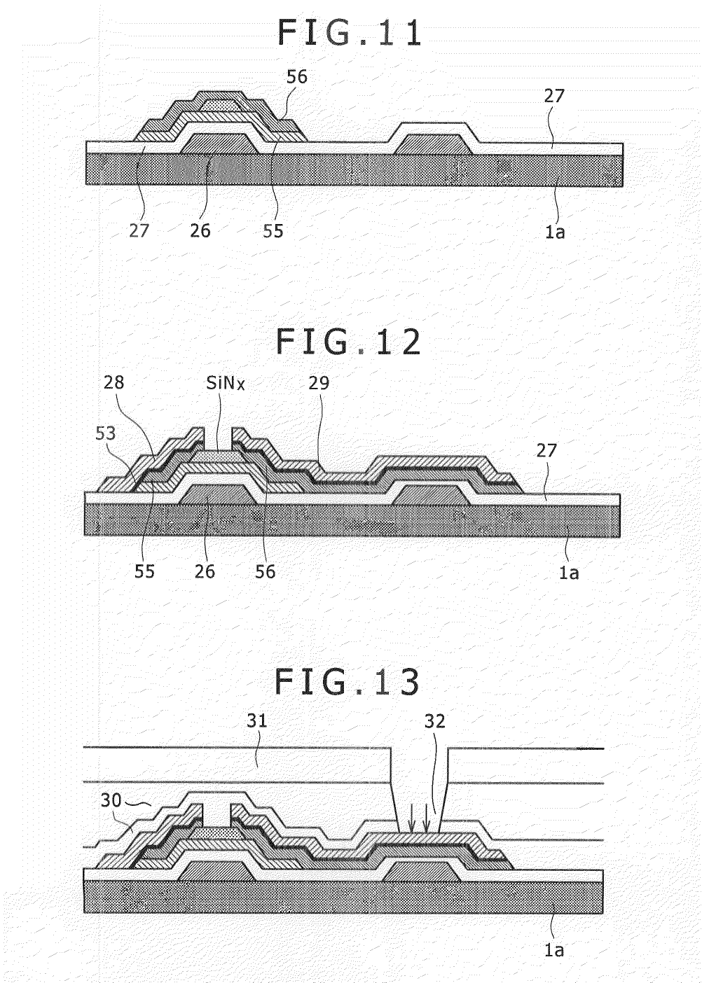

Subsequently, by back side light exposure with the gate electrode 26 as a mask, as shown in FIG. 10, the silicon nitride film (SiNx) is patterned to form a channel protective film. Further, thereon, a phosphorus-doped n⁺ type hydrogenated amorphous silicon film (n⁺ a-Si—H) 56 with a thickness of about 50 nm is deposited. Then, as shown in FIG. 11, the hydrogenated amorphous silicon film (a-Si—H) 55 and the n⁺ type hydrogenated amorphous silicon film (n⁺ a-Si—H) 56 are patterned.

Then, thereon, with a sputtering process, a barrier metal layer (MO film) 53 with a thickness of about 50 nm, and Al alloy films 28 and 29 with a thickness of about 300 nm are sequentially stacked. The deposition temperature of sputtering was set at 150° C. Then, by performing patterning as shown in FIG. 12, the source electrode 28 integral with the signal line, and the drain electrode 29 to be directly connected to the transparent pixel electrode are formed. Further, with the source electrode 28 and the drain electrode 29 as a mask, the n⁺ type hydrogenated amorphous silicon film (n⁺ a-Si—H) 56 on the channel protective film (SiNx) is dry etched, and is removed.

Then, as shown in FIG. 13, by means of, for example, a plasma CVD device, a silicon nitride film 30 with a thickness of about 300 nm is deposited to form a protective film. The deposition temperature at this step is, for example, about 250° C. for performing deposition. Then, on the silicon nitride film 30, a photoresist layer 31 is formed, and then, the silicon nitride film 30 is patterned. Thus, contact holes 32 are formed in the silicon nitride film 30 by, for example, dry etching. Simultaneously, a contact hole (not shown) is formed at a portion for establishing a connection with the TAB on the gate electrode at the panel end.

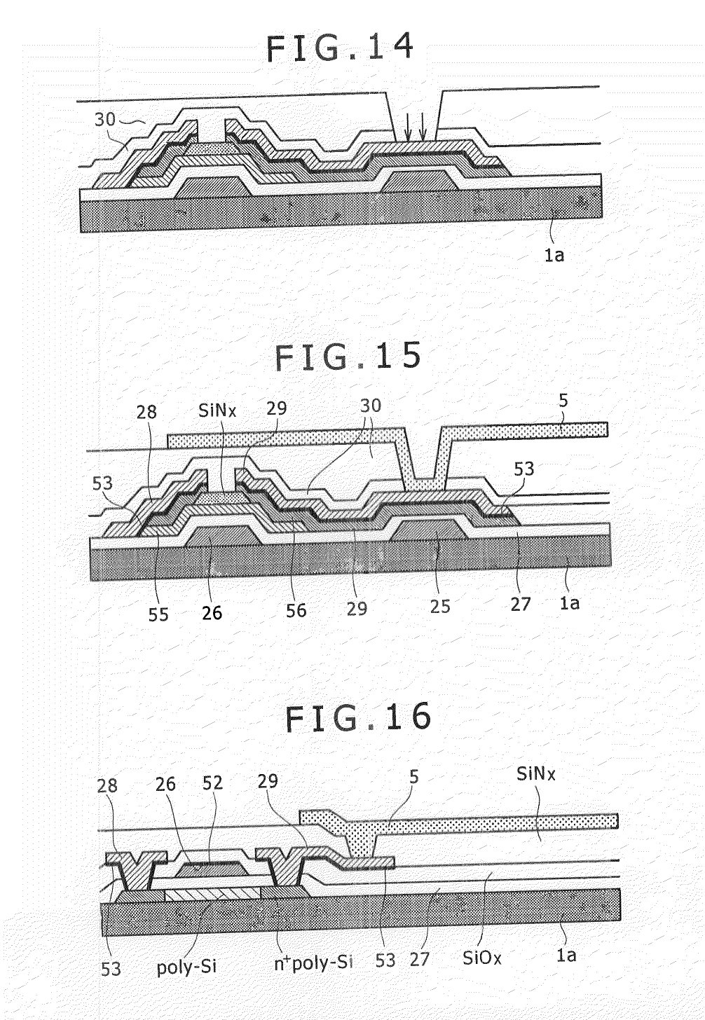

Then, after undergoing an ashing step by, for example, an oxygen plasma, as shown in FIG. 14, for example, with an amine-based peeling liquid, the photoresist layer 31 is peeled. Finally, within a range of, for example, the storage time (about 8 hours), as shown in FIG. 15, an ITO film with a thickness of, for example, about 40 nm is deposited, and patterned by wet etching, thereby to form the transparent pixel electrode 5. Simultaneously, the ITO film is patterned for bonding with the TAB at the connection portion with the TAB of the gate electrode at the panel end, resulting in the completion of a TFT substrate 1.

In the TFT substrate thus manufactured, the drain electrode 29 and the transparent pixel electrode 5 are in direct contact with each other.

In the foregoing description, as the transparent pixel electrode 5, the ITO film was used. However, an IZO film may also be used. Whereas, as the active semiconductor layer, polysilicon may be used in place of amorphous silicon (see the second embodiment described later).

By using the TFT substrate thus obtained, and with, for example, the following method, the liquid crystal display device shown in FIG. 6 is completed.

First, the surface of the TFT substrate 1 manufactured in the foregoing manner is coated with, for example, polyimide, and is dried, and then, is subjected to a rubbing treatment to form an alignment film.

On the other hand, for the opposing substrate 2, for example, chromium (Cr) is patterned in a matrix on the glass substrate, thereby to form a light shield film 9. Then, in the gaps in the light shield film 9, red, green, and blue color filters 8 made of a resin are formed. On the light shield film 9 and the color filters 8, a transparent electroconductive film such as an ITO film is disposed as a common electrode 7, thereby to form the opposing electrode. Then, the uppermost layer of the opposing electrode is coated with, for example, polyimide, and dried, and then subjected to a rubbing treatment, thereby to form an alignment film 11.

Then, the TFT substrate 1 and the side of the opposing substrate 2 on which the alignment film 11 is formed are disposed so as to face each other. Thus, with a sealing material 16 made of a resin or the like, two sheets of the TFT substrate 1 and the opposing substrate 2 are bonded together except for the sealing port of a liquid crystal. At this step, a spacer 15 is interposed between the TFT substrate 1 and the opposing substrate 2. By this or other configurations, the gap between the two substrates is kept generally constant.

The void cell thus obtained is placed in vacuum, and is gradually returned to atmospheric pressure with the sealing port immersed in liquid crystal. As a result, a liquid crystal material including liquid crystal molecules is injected into the void cell, thereby to form a liquid crystal layer. Thus, the sealing port is sealed. Finally, onto the outer opposite sides of the void cell, polarizing plates 10 are bonded, thereby to complete the liquid crystal display.

Then, as shown in FIG. 6, a driver circuit 13 for driving the liquid crystal display device is electrically connected to the liquid crystal display, and is disposed on the side part or the back side part of the liquid crystal display. Then, the liquid crystal display is held by a holding frame 23 including an opening serving as the display side of the liquid crystal display, a backlight 22 serving as a surface light source, a light guide plate 20, and the holding frame 23, resulting in the completion of the liquid crystal display device.

### Second Embodiment

With reference to FIG. 16, an embodiment of the polysilicon TFT substrate will be described in details.

FIG. 16 is a schematic cross-sectional illustrative view for illustrating a preferred embodiment of a top gate type TFT substrate in accordance with the present invention.

This embodiment is mainly different from the first embodiment described above in that polysilicon is used in place of amorphous silicon as the active semiconductor layer, and in that a TFT substrate of not bottom gate type but top gate type is used. Particularly, the polysilicon TFT substrate of this embodiment shown in FIG. 16 is different from the amorphous silicon TFT substrate shown in FIG. 7 described above in that the active semiconductor film is formed of a polysilicon film (poly-Si) not doped with phosphorus, and a polysilicon film (n⁺ poly-Si) ion-implanted with phosphorus or arsenic. Whereas, the signal line is formed in such a manner as to cross with the scanning line via the interlayer insulating film (SiOx).

Also in this embodiment, the barrier metal layer formed on the source electrode 28 and the drain electrode 29 can be omitted.

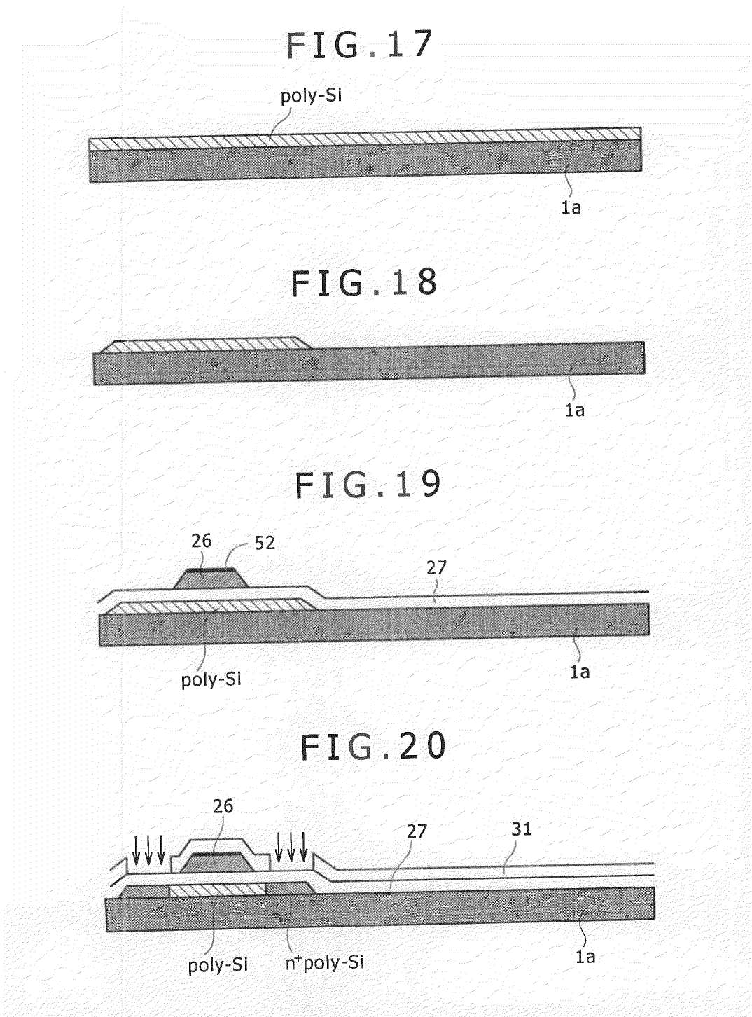

Then, with reference to FIGS. 17 through 23, a description will be given to one example of the manufacturing method of the polysilicon TFT substrate in accordance with the present invention shown in FIG. 16. The thin-film transistor is a polysilicon TFT using a polysilicon film (poly-Si) as the semiconductor layer. In FIGS. 17 through 23, the same reference numeral and signs as those in FIG. 16 are given.

First, on the glass substrate 1a, with, for example, a plasma CVD process, a silicon nitride film (SiNx) with a thickness of about 50 nm, a silicon oxide film (SiOx) with a thickness of about 100 nm, and a hydrogenated amorphous silicon film (a-Si—H) with a thickness of about 50 nm are deposited at a substrate temperature of about 300° C. Then, in order to convert the hydrogenated amorphous silicon film (a-Si—H) into polysilicon, a heat treatment (at about 470° C. and for about 1 hour) and laser annealing are performed. A dehydrogenation treatment is performed. Then, by means of, for example, an excimer laser annealing device, a laser light with an energy of about 230 mJ/cm² is applied to the hydrogenated amorphous silicon film (a-Si—H). This results in a polysilicon film (poly-Si) with a thickness of about 0.3 μm (FIG. 17).

Then, as shown in FIG. 18, the polysilicon film (poly-Si) is patterned by plasma etching or the like. Then, as shown in FIG. 19, a silicon oxide film (SiOx) with a thickness of about 100 nm is deposited to form a gate insulating film 27. On the gate insulating film 27, by sputtering or the like, an Al alloy thin film with a thickness of about 200 nm, and a barrier metal layer (Mo thin film) 52 with a thickness of about 50 nm are stacked, followed by patterning with a process of plasma etching or the like. This results in the formation of the gate electrode 26 integral with the scanning line.

Subsequently, as shown in FIG. 20, a mask is formed of a photoresist 31. Thus, by means of, for example, an ion implantation device, for example, phosphorus is doped at about 1×10¹⁵ atoms/cm² at about 50 keV, thereby to form an n⁺ type polysilicon film (n⁺ poly-Si) in a part of the polysilicon film (poly-Si). Then, the photoresist 31 is peeled, and the film is heat-treated at, for example, about 500° C., thereby to diffuse phosphorus.

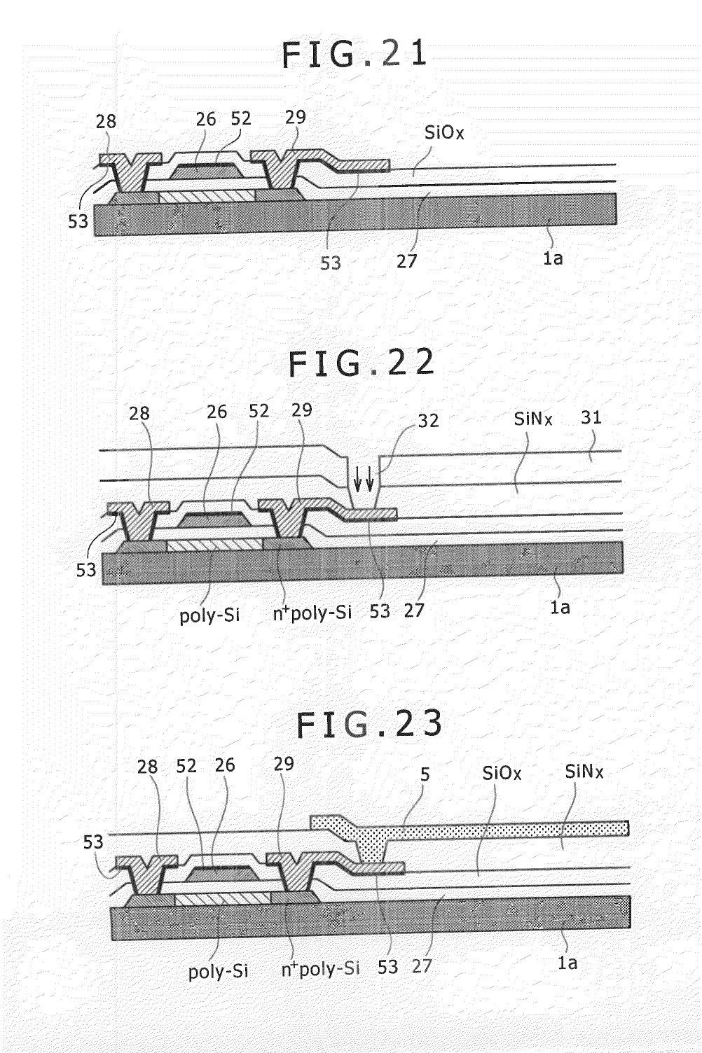

Then, as shown in FIG. 21, by means of, for example, a plasma CVD device, a silicon oxide film (SiOx) with a thickness of about 500 nm is deposited at a substrate temperature of about 250° C., thereby to form an interlayer insulating film. Then, similarly, using a mask patterned with a photoresist, the silicon oxide films of the interlayer insulating film (SiOx) and the gate insulating film 27 are dry etched, thereby to form contact holes. By sputtering, a barrier metal layer (Mo film) 53 with a thickness of about 50 nm and an Al alloy film with a thickness of about 450 nm are deposited, followed by patterning. This results in the formation of the source electrode 28 and the drain electrode 29 integral with the signal line. As a result, the source electrode 28 and the drain electrode 29 are respectively brought into contact with the n⁺ type polysilicon film (n⁺ poly-Si) via their respective contact holes.

Then, as shown in FIG. 22, by means of a plasma CVD device or the like, a silicon nitride film (SiNx) with a thickness of about 500 nm is deposited at a substrate temperature of about 250° C., thereby to form an interlayer insulating film. On the interlayer insulating film, a photoresist layer 31 is formed, and then, the silicon nitride film (SiNx) is patterned. Thus, by, for example, dry etching, a contact hole 32 is formed in the silicon nitride film (SiNx).

Then, as shown in FIG. 23, after undergoing, for example, an ashing step with an oxygen plasma, as with the first embodiment described above, by the use of an amine-based peeling liquid, or the like, the photoresist is peeled. Then, an ITO film is deposited, and patterning by wet etching is performed, thereby to form a transparent pixel electrode 5.

In the polysilicon TFT substrate manufactured in this manner, the drain electrode 29 is in direct contact with the transparent pixel electrode 5.

Then, in order to stabilize the characteristics of the transistor, annealing is performed, for example, at about 250° C. for about 1 hour, so that a polysilicon TFT array substrate is completed.

With a TFT substrate in accordance with the second embodiment, and a liquid crystal display device including the TFT substrate, the same effects as those with the TFT substrate in accordance with the first embodiment described above can be obtained.

By the use of the TFT array substrate obtained in this manner, the liquid crystal display device shown in FIG. 6 is completed in the same manner as with the TFT substrate of the first embodiment described above.

### EXAMPLES

Below, by way of examples, the present invention will be more specifically described. However, the present invention is not limited by the following examples. It is naturally understood that modifications may be properly made and practiced within the scope adaptable to the gists described above and below. All of these are included in the technical scope of the present invention.

### Example 1-1

From the viewpoint of the corrosion resistance, black spot generation caused after peeling liquid washing was evaluated. Black spots generated after peeling and washing are, as understood from the foregoing description, generated from the intermetallic compounds as the starting points. With an Al alloy on a glass substrate (EAGLE 2000 manufactured by Corning, 2 inch in diameter, 0.7 mm in gage), using a sputtering device, an Al alloy film with a film thickness of 300 nm was deposited. By means of a heat treatment furnace of a 300° C. nitrogen atmosphere, a 30-minute heat treatment was performed. The inside of the furnace was held at 300° C. under a nitrogen flow, and then, the substrate was charged therein. After charging of the substrate, 15 minutes was taken to wait for stabilization of the furnace temperature, and another 30-minute heat treatment was performed. Then, a peeling liquid containing monoethanolamine as a main component (TOK106 manufactured by TOKYO OHKA KOGYO Co., Ltd.) was diluted with pure water to 55,000 times, thereby to prepare an alkaline liquid with a pH of 10. The substrate after the heat treatment was immersed therein for 5 minutes, and was rinsed with pure water for 1 minute. Then, the substrate was dried with nitrogen blow, and observed by a microscope (magnification 1000 times). During observation, when a contrast is clearly caused, and is visually confirmed as a black spot, this is judged as a defect. The results are shown in Table 1. It is indicated as follows. From the viewpoint of the corrosion resistance, individual intermetallic compounds are refined, which can disperse and reduce the size of the starting points of corrosion. This improves the corrosion resistance (it has been shown that at least the anxiety about the corrosion resistance in view of the appearance can be canceled or relieved.)

Further, for evaluation of the developing solution resistance, using a film deposited to a thickness of 300 nm by sputtering, the film loss amount upon immersion in a developing solution (TMAH 2.38 wt % aqueous solution) was measured by means of a profilometer, and was converted into the etching rate. The results are shown together in Table 1. The etching rate of pure Al is 20 nm/min. However, an excessively higher etching rate than this is not desirable.

Incidentally, for evaluation of “contact resistance (Ω), CVD temperature 250° C.” in Table 1, a sample whose contact resistance value with ITO upon CVD deposition at 250° C. is 99Ω or less is rated as A; a sample of 100 to 499Ω, as B; a sample of 500 to 999Ω, as C; and a sample of 1000Ω or more, as D.

Further, for evaluation of “crater corrosion density (marks/100 μm²) in Table 1, a sample having the value of 0.9 or less is rated as A; a sample of 1 to 9.9, as B; a sample of 10 to 50, as C; and a sample of more than 50, as D.

Whereas, for evaluation of “heat resistance (350° C.)” in Table 1, rating is indicated with “A or B”. This represents the record when the presence or the absence of hillocks and the surface conditions in a heat treatment in vacuum at 350° C. for 30 minutes have been observed. “A” represents “no hillock”; and “B” represents “no hillock but some roughness observed on the surface”.

Further, for evaluation of “intermetallic compound size (150 nm or less)” in Table 1, a sample in which the maximum diameter of the intermetallic compound size is 150 nm or less is rated as A; and a sample of more than 150 nm, as B.

Whereas, for evaluation of “X1—X2 and Al—X1—X2 to total ratio of 50% or more” in Table 1, a sample in which the total area of the intermetallic compounds of X1—X2 and Al—X1—X2 is 50% or more of the total area of all the intermetallic compounds is rated as A; and a sample of less than 50%, as B.

TABLE 1

| | | Contact resistance | | | | Electric resistivity |
|---|---|---|---|---|---|---|
| | | (Ω) | | | | after deposition |
| Experiment | | CVD temperature | | Crater corrosion | | at 250° C. |
| No. | Alloy composition | 250° C. | | density (marks/100 μm²) | | (μΩ · cm) |
| 1 | Al—0.05Ni—0.5Cu—0.3La | 3230 | D | 0 | A | 4.2 |
| 2 | Al—0.1Ni—0.5Cu—0.3La | 850 | B | 0.1 | A | 4.3 |
| 3 | Al—1Ni—0.5Cu—0.3La | 227 | B | 1 | B | 4.6 |
| 4 | Al—2Ni—0.5Cu—0.3La | 72 | A | 24.7 | C | 4.7 |
| 5 | Al—6Ni—0.5Cu—0.3La | 66 | A | 44 | C | 6.5 |
| 6 | Al—1Ni—0.1Cu—0.3La | 400 | B | 2.2 | B | 4.4 |
| 7 | Al—1Ni—1Cu—0.3La | 175 | B | 7.5 | B | 4.7 |
| 8 | Al—1Ni—2Cu—0.3La | 164 | B | 14.4 | C | 4.9 |
| 9 | Al—1Ni—3Cu—0.3La | 159 | B | 28 | C | 5.1 |
| 10 | Al—1Ni—0.5Cu—0.1La | 208 | B | 2 | B | 4.4 |
| 11 | Al—1Ni—0.3La | 429 | B | 2.4 | B | 4.2 |
| 12 | Al—2Ni—0.3La | 81 | A | 19.1 | C | 4.5 |
| 13 | Al—0.05Ni—0.5Ge—0.5Nd | 313000 | D | 0.7 | A | 3.8 |
| 14 | Al—0.08Ni—0.5Ge—0.5Nd | 934 | C | 2 | B | 4 |
| 15 | Al—0.1Ni—0.5Ge—0.5Nd | 833 | C | 1.7 | B | 4.9 |
| 16 | Al—0.12Ni—0.5Ge—0.5Nd | 435 | B | 1 | B | 4.9 |
| 17 | Al—0.15Ni—0.5Ge—0.5Nd | 277 | B | 3.7 | B | 5.0 |
| 18 | Al—0.2Ni—0.5Ge—0.5Nd | 92 | A | 4.3 | B | 5.4 |
| 19 | Al—0.1Ni—0.5Ge—0.2Nd | 190 | B | 0.03 | A | 3.6 |
| 20 | Al—0.15Ni—0.5Ge—0.2Nd | 110 | B | 1.5 | B | 3.8 |
| 21 | Al—0.2Ni—0.5Ge—0.2Nd | 185 | B | 2.6 | B | 3.7 |
| 22 | Al—0.1Ni—0.5Ge—0.25Nd | 440 | B | 0.04 | A | 3.4 |
| 23 | Al—0.1Ni—0.5Ge—0.3Nd | 1000 | D | 0.07 | A | 3.5 |
| 24 | Al—0.15Ni—0.5Ge—0.75Nd | 476 | B | 0 | A | 5.2 |
| 25 | Al—0.2Ni—0.5Ge—1Nd | 1500 | D | 0.02 | A | 5.7 |
| 26 | Al—0.1Ni—0.5Ge—0.2Nd—0.2Cu | 570 | C | 0.12 | A | 3.8 |
| 27 | Al—0.15Ni—0.5Ge—0.2Nd—0.2Cu | 230 | B | 0.7 | A | 3.9 |
| 28 | Al—0.2Ni—0.5Ge—0.2Nd—0.2Cu | 680 | C | 1.3 | B | 3.8 |
| 29 | Al—0.5Ni—0.5Ge—0.3La | 210 | B | 0.1 | A | 4.1 |
| 30 | Al—1Ni—0.5Ge—0.3La | 480 | B | 3 | B | 4.4 |
| 31 | Al—0.5Ni—0.5Ge—0.1La | 140 | B | 0.1 | A | 4 |
| 32 | Al—0.5Cu—0.3La | 1202 | D | 1.1 | B | 4.2 |
| 33 | Al—1Ni—0.5Cu—0.3Nd | 199 | B | 1.1 | B | 4.3 |
| 34 | Al—1Ni—0.5Cu—0.3Gd | 231 | B | 1.1 | B | 4.3 |
| 35 | Al—1Ni—5Cu—0.3La | 120 | B | 51 | D | 4.4 |
| 36 | Al—0.2Co—0.3La | 1000 | D | 0 | A | 3.8 |
| 37 | Al—0.5Co—0.3La | 490 | B | 0 | A | 4.1 |
| 38 | Al—0.1Co—0.5Ge—0.2La—0.1Cu | 201 | B | 9.5 | B | 3.8 |
| 39 | Al—0.1Co—0.5Ge—0.2La—0.2Cu | 532 | C | 3.3 | B | 3.8 |
| 40 | Al—0.1Co—0.5Ge—0.2La—0.3Cu | 563 | C | 0.1 | A | 3.7 |
| 41 | Al—0.2Co—0.5Ge—0.2La | 254 | B | 13.5 | C | 4 |
| 42 | Al—0.2Co—0.5Ge—0.3La | 331 | B | 8.2 | B | 3.9 |
| 43 | Al—0.2Co—0.5Ge—0.2Nd | 161 | B | 0.5 | A | 3.9 |
| 44 | Al—0.1Co—0.5Ge—0.2Nd | 113 | B | 0.8 | A | 3.6 |
| 45 | Al—0.2Co—0.5Ge—0.3Nd | 134 | B | 0.9 | A | 3.8 |
| 46 | Al—0.1Co—0.5Ge—0.3Nd | 120 | B | 5.3 | B | 3.7 |
| 47 | Al—0.1Co—0.5Ge—0.2La—0.3Cu | 215 | B | 3.8 | B | 4.2 |
| 48 | Al—0.1Co—0.5Ge—0.2Nd—0.3Cu | 103 | B | 0.2 | A | 4.1 |
| 49 | Al—0.2Co—0.5Ge—0.1La | 160 | B | 0 | A | 3.8 |
| 50 | Al—0.2Co—0.5Ge—0.3La | 310 | B | 0 | A | 4 |
| 51 | Al—0.2Co—0.5Cu—0.3La | 355 | B | 0 | A | 3.9 |
| 52 | Al—1Co—0.5Ge—0.3La | 267 | B | 0.1 | A | 4.6 |
| 53 | Al—8Co—0.5Ge—0.3La | 144 | B | 23 | C | 6.6 |
| 54 | Al—0.5Ge—0.3La | 1550 | D | 0 | A | 3.5 |
| 55 | Al—1Ag—0.5Cu—0.3La | 350 | B | 6.5 | B | 4.5 |
| 56 | Al—1Ag—0.5Ge—0.3La | 389 | B | 5 | B | 4.5 |
| 57 | Al—1Zn—0.5Cu—0.3La | 440 | B | 3.2 | B | 4 |
| 58 | Al—1Zn—0.5Ge—0.3La | 484 | B | 3 | B | 4 |
| 59 | Al—1Ni—1Cu | 140 | B | 2.5 | B | 4.1 |
| 60 | Al—4Ni—1Cu | 58 | A | 29 | C | 5.2 |
| 61 | Al—4Co—1Ge | 101 | B | 11.5 | C | 4.9 |
| 62 | Al—2Ni—1Cu—2La | 135 | B | 4 | B | 8 |
| 63 | Al—2Co—1Ge—2La | 188 | B | 1.5 | B | 7.6 |

| | | | | | 150-nm or more |
|---|---|---|---|---|---|
| | Developing solution | Heat | Intermetallic | X1-X2 and Al-X1-X2 | intermetallic |
| Experiment | etching rate | resistance | compound size | to total ratio of | compound density |
| No. | (nm/min.) | (350° C.) | 150 nm or less | 50% or more | (compounds/100 μm²) |
| 1 | 22 | A | A | A | <1 |
| 2 | 22 | A | A | A | <1 |
| 3 | 31 | A | A | A | <1 |
| 4 | 51 | A | A | A | <1 |
| 5 | 89 | A | A | A | <1 |
| 6 | 55 | A | A | A | <1 |
| 7 | 44 | A | A | A | <1 |
| 8 | 48 | A | A | A | <1 |
| 9 | 60 | A | A | A | <1 |
| 10 | 59 | B | A | A | <1 |
| 11 | 61 | A | B | — | 5 |
| 12 | 66 | A | B | — | 31 |
| 13 | 16 | A | A | A | <1 |
| 14 | 19 | A | A | A | <1 |
| 15 | 18 | A | A | A | <1 |
| 16 | 17 | A | A | A | <1 |
| 17 | 18 | A | A | A | <1 |
| 18 | 24 | A | A | A | <1 |
| 19 | 14 | A | A | A | <1 |
| 20 | 14 | A | A | A | <1 |
| 21 | 14 | A | A | A | <1 |
| 22 | 14 | A | A | A | <1 |
| 23 | 9 | A | A | A | <1 |
| 24 | 11 | A | A | A | <1 |
| 25 | 8 | A | A | A | <1 |
| 26 | 12 | A | A | A | <1 |
| 27 | 12 | A | A | A | <1 |
| 28 | 14 | A | A | A | <1 |
| 29 | 30 | A | A | A | <1 |
| 30 | 39 | A | A | A | <1 |
| 31 | 35 | B | A | A | <1 |
| 32 | 18 | A | A | A | <1 |
| 33 | 25 | A | A | A | <1 |
| 34 | 25 | A | A | A | <1 |
| 35 | 65 | A | A | A | <1 |
| 36 | 10 | A | A | — | <1 |
| 37 | 88 | A | A | — | <1 |
| 38 | 25 | A | A | A | <1 |
| 39 | 22 | A | A | A | <1 |
| 40 | 24 | A | A | A | <1 |
| 41 | 70 | B | A | A | <1 |
| 42 | 55 | A | A | A | <1 |
| 43 | 44 | B | A | A | <1 |
| 44 | 29 | B | A | A | <1 |
| 45 | 35 | A | A | A | <1 |
| 46 | 21 | A | A | A | <1 |
| 47 | 26 | A | A | A | <1 |
| 48 | 23 | A | A | A | <1 |
| 49 | 29 | B | A | A | <1 |
| 50 | 30 | A | A | A | <1 |
| 51 | 40 | A | A | A | <1 |
| 52 | 49 | A | A | A | <1 |
| 53 | 120 | A | A | B | <1 |
| 54 | 17 | A | A | — | <1 |
| 55 | 20 | A | A | A | <1 |
| 56 | 20 | A | A | A | <1 |
| 57 | 19 | A | A | A | <1 |
| 58 | 16 | A | A | A | <1 |
| 59 | 75 | B | A | A | <1 |
| 60 | 98 | B | A | A | <1 |
| 61 | 108 | B | A | A | <1 |
| 62 | 23 | A | A | A | <1 |
| 63 | 41 | A | A | A | <1 |

In Table 1, there are shown the contact resistance with ITO upon CVD deposition at 250° C., the density of black spots (exactly crater corrosion density) and the electric resistivity of the film itself. Whereas, there are also shown the density of black spots and 150 nm or more intermetallic compounds. Next, respective experiments thereof will be evaluated.

First, a description will be given to the a production process of each sample, and the evaluation method of each item. The contact resistance was evaluated using a contact chain. Fifty contact holes are continuous. First, on a glass substrate, a 300 nm Al alloy is deposited by sputtering. Then, a wire is formed by photolithography and etching. Thereafter, SiN is deposited to 300 nm at a temperature of 250° C. by CVD. Again, by photolithography, 10-μm-square contact holes are formed, and SiN is etched by Ar/SF₆/O₂ plasma etching. Then, resist peeling is performed using oxygen plasma ashing and TOK106. After water washing, a transparent electroconductive film (amorphous ITO) is sputtering deposited with a film thickness of 200 nm. Incidentally, the contact resistance in Table 1 indicates the value converted per contact hole.

For experiment No. 1, Ni was in a very small amount, and hence the contact resistance was high. Thus, the direct contact which is the precondition in the first place in the present invention could not be implemented. However, the electric resistivity of the film itself was held low due to the low content of Ni. Incidentally, the corrosion resistance which is the problem of the present invention was improved by addition of Cu which is an X2 element. This matches the following: both of respective requirements of the maximum diameter of the intermetallic compound size: 150 nm or less (which may be hereinafter referred to as “intermetallic compound size requirement”) and the area ratio of X1—X2 and Al—X1—X2: 50% or more (which may be hereinafter referred to as “intermetallic compound area requirement” are rated as A. Incidentally, in terms of the heat resistance additionally mentioned as a property desired to be improved, an excellent value is shown due to addition of La which is an X3 element.

For experiment No. 2, Ni was included in a sufficient amount, and hence the contact resistance was improved than that of experiment No. 1. Also in terms of other items which are the problems of the present invention, non-problematic excellent results are shown.

For experiment No. 3, Ni was in a further increased amount, and hence the contact resistance was further improved. On the other hand, the electric resistivity of the Al alloy film itself was slightly increased, but was not practically problematic. In terms of the corrosion resistance which is the problem of the present invention, further inclusive of the heat resistance, excellent results were achieved.

For experiment No. 4, Ni was in a further increased amount, and hence the contact resistance was still more improved. The electric resistivity of the Al alloy film itself was very slightly increased, but was not practically problematic. The corrosion resistance, which is the problem of the present invention, was improved to a practically non-problematic level. In terms of the corrosion resistance, further inclusive of the heat resistance, excellent results were achieved.

For experiment No. 5, Ni was in a very large amount, and hence the contact resistance was further improved. The electric resistivity and the corrosion resistance of the Al alloy film itself were slightly reduced, but were not practically problematic in view of the heat resistance inclusive.

For experiment No. 6, Cu was in a smaller amount as compared with experiment No. 3. Accordingly, the etching rate with the developing solution was slightly increased (became higher than 20 mm/min of pure Al). However, there was no problem in terms of corrosion resistance. Further, the heat resistance was also favorable.

For experiment No. 7, Cu was in a significantly increased amount as compared with experiment No. 6, and hence the contact resistance was further improved. On the other hand, the corrosion resistance and the heat resistance were also very favorable.

For experiment No. 8, Cu was in a further larger amount as compared with experiment No. 7, resulting in a slight disadvantage in corrosion resistance. However, this was not at a practically problematic level. The heat resistance was also favorable.

For experiment No. 9, Cu was in a still larger amount as compared with experiment No. 8, resulting in a slight disadvantage in corrosion resistance or developing solution etching rate. However, practically, a slight problem may occur, but, on the whole, stable properties were shown.

For experiment No. 10, the Cu content was returned to the level of experiments Nos. 1 to 5. This resulted in a slight disadvantage in developing solution etching rate. However, on the whole, it can be said that there is no practical problem.

For experiment Nos. 11 and 12, the element X2 was not included. For this reason, problems occurred in the “intermetallic compound size requirement” and the “intermetallic compound area requirement”. Further, the “density of 150 nm or more intermetallic compounds” is also 1 compound/100 μm² or more, which leaves a problem in corrosion resistance. Thus, the problem of the present invention has not yet been solved. Incidentally, “−” in the table means that no inclusion of the element X2 results in no formation of the intermetallic compounds of X1—X2 and X1—X2—X3.

Also for experiment Nos. 13 to 28, the element to be added, and the content were changed. In all cases, the 150 nm or more intermetallic compound density was less than one compound/100 μm².

For experiment Nos. 29 to 31, both the elements X1 and X2 were included in proper amounts, which could solve the problem of the present invention without a trouble.

For experiment No. 32, the element X1 was not included. For this reason, the direct contact which is the assumed problem of the present invention cannot be implemented.

For experiments Nos. 33 and 34, the element X3 (La) of the experiment No. 3 was only replaced with Nd or Gd. Resultantly, these samples can compare favorably with experiment No. 3.

For experiment No. 35, Cu which is the element X2 was further increased in amount in excess of that of the experiment No. 9. Accordingly, the crater corrosion density and the developing solution etching rate were slightly deteriorated. Thus, these samples may be unable to be recommended according to the intended purpose.

Also for experiment Nos. 36 and 37, the element X2 was not included. Accordingly, unfavorably, the contact resistance was too high, and the developing solution etching rate was too high. The “intermetallic compound area requirement” could not also be satisfied.

Also for experiment Nos. 38 to 48, the element to be added, and the content were changed. In all cases, the 150 nm or more intermetallic compound density was less than one compound/100 μm²

Experiment Nos. 49, 50, and 51 are examples in each of which the element X1 was changed from Ni to Co, and X2 was included together in a proper amount. Each amount of Co added in these experiment examples was remarkably lower than the Ni addition amount in the respective experiment examples. However, direct contact was sufficiently comparable to that of the sample with a large Ni addition amount. No problem was observed also in terms of the corrosion resistance and the heat resistance. Thus, the problem of the present invention could be favorably solved without any trouble.

For experiment No. 52, the Co addition amount was increased to as much as the Ni addition amounts in the respective experiment examples in each of which Ni was added. Accordingly, the contact resistance was improved than that of experiment No. 51. Excellent effects were shown in terms of all the evaluation items including others.

For experiment No. 53, the “intermetallic compound area requirement” was in an undesirable state presumably due to the very large Co addition amount. This unfavorably caused a remarkable increase in developing solution etching rate.

For experiment No. 54, the element X1 was not included. For this reason, the direct contact which is the assumed problem of the present invention could not be implemented.

For experiment Nos. 55 to 58, the element X1 was changed to Ag and Zn, and Cu and Ge as X2 were included in proper amounts. This can solve all the problems of the present invention.

For experiment Nos. 59 to 61, the elements X1 and X2 were included, but the element X3 was not included. For this reason, the contact resistance and the electric resistivity were low, and the corrosion resistance was also favorable. However, as compared with the example further including the element X3, the heat resistance was somewhat reduced.

Experiment Nos. 62 and 63 are examples in each of which the content of the element X3 was as much as the content of Ni or Co. For this reason, the electric resistivity slightly increased. However, the preferred upper limit of the content of the element X3 was satisfied, and hence the heat resistance was favorable.

From these results, the addition amount of the element X1 is 0.05 to 6 at %, preferably 0.08 to 4 at %, further preferably 0.1 to 4 at %, still further preferably 0.1 to 2.5 at %, and more preferably 0.2 to 1.5 at %. The addition amount of the element X2 is 0.1 to 2 at %, and preferably 0.3 to 1.5 at %. Then, the addition amount of the elements X3 such as La, Nd, Dy, and Gd is 0.05 to 2 at %, and further preferably 0.1 to 0.5 at %.

The comprehensive evaluation of respective elements X1, X2, and X3 will be shown. From the viewpoint of the contact stability, there is a feature that Co is effective even in a smaller amount as compared with Ni. However, the elements are preferable in that all of them can provide stable performances. On the other hand, from the viewpoint of the developing solution resistance, Co is slightly inferior to Ni.

However, in terms of the electric resistivity, Co is slightly lower as compared with Ni addition. Further, black spot generation due to the peeling liquid is hardly caused with Co in a low-addition region. Further, Cu addition and Ge addition have almost the same effect, so that the electric resistance is slightly reduced, and an improvement is also observable in contact resistance. Whereas, in terms of the corrosion resistance, a favorable improvement effect is observable particularly in the Ni or Co low-addition region.

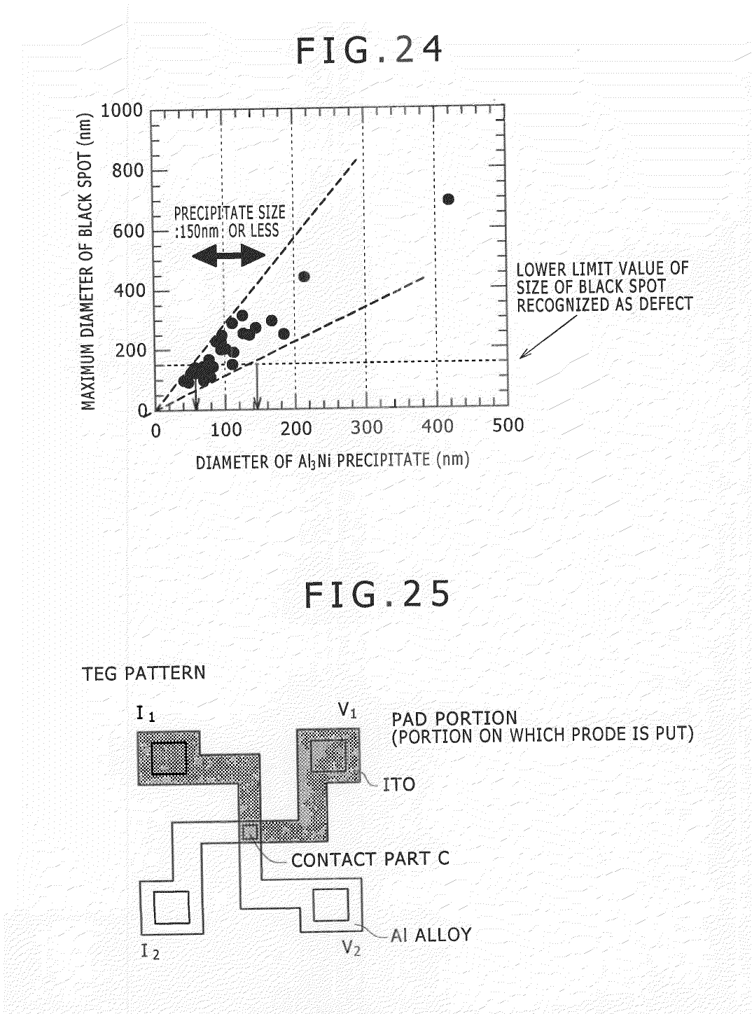

Then, the black spots judged as defects by a microscope were observed by a SEM (30000 times to 50000 times). As a result, the size was found to be more than 150 nm. In Table 1, the 150 nm or more intermetallic compound density was found to be one compound/100 μm² or more. The films not recognized as defective products by the method were observed by means of a SEM (30000 times to 50000 times) and a plan-view TEM (300000 times). As a result, the size of the intermetallic compound was found to be 150 nm or less. According to statistical analysis using a large number of samples, the relation between the size of the one recognized as a black spot and the size of the actual intermetallic compound is as shown in FIG. 24 from the results of observation using Al—Ni—La. The size of the intermetallic compound is required to be 150 nm or less at maximum.

From the results up to this point, considering on the assumption that the size of the black spot is roughly proportional to the size of the intermetallic compound serving as the starting point, it has been found that the precipitation form and size of the intermetallic compound are required to be controlled in order to suppress black spots.

### Example 2-1

In this example, in order to examine the effect of the arithmetic mean roughness Ra of the contact surface of the Al alloy film exerted on the contact resistance, there was conducted an experiment in which the immersion conditions of the alkali solution are variously changed to control Ra.

Specifically, first, a non-alkali glass plate (gage: 0.7 mm) was used as a substrate. On the surface, two kinds of Al alloy films having different Ni contents were deposited by DC magnetron sputtering at room temperature (film thickness 300 nm). Specifically, as a first Al alloy film, an Al-0.6 at % Ni-0.5 at % Cu-0.3 at % La alloy film was used; and as a second Al alloy film, an Al-1.0 at % Ni-0.5 at % Cu-0.3 at % La alloy film was used.

These Al alloy films were heat-treated at 320° C. for 30 minutes, thereby to form precipitates (intermetallic compounds). According to the method, the maximum diameter of the intermetallic compound size was measured. As a result, in all cases, the maximum diameter was found to be 50 to 130 nm.

Each Al alloy film after the heat treatment was immersed in pure water (pH 7.0) or an alkali aqueous solution at each corresponding pH and immersion time shown in Tables 2 and 3 below. Thus, the surface was wet-etched. Incidentally, for preparing an alkali aqueous solution with a pH of 9.5 or more, an alkali solution of 60 vol % of monoethanolamine and 40 vol % of dimethylsulfoxide (DMSO) was used, and was diluted with water to the pH shown in Table 2 below. On the other hand, for alkali aqueous solutions with a pH of 9.0 or less (pH 8.0 and 9.0), an aqueous ammonia solution was used, and was diluted with water to adjust the pH.

Each Al alloy film was immersed therein for a prescribed time, and then, was washed with water/dried. Thus, the arithmetic mean roughness Ra of the surface was measured by an atomic force microscope (AFM, measurement area: 5×5 mm) (reference length: 0.08 mm, evaluation length: 0.01 mm). These results are shown in Tables 2 and 3 below.

On the surface of each Al alloy film measured for the Ra, as an oxide electroconductive film, an ITO film (film thickness: 200 nm) was deposited by DC magnetron sputtering. Then, by patterning with photolithography and etching, a contact resistance measurement pattern (contact area 10 μm×10 μm) was formed. Thus, the contact resistance of the Al alloy film/ITO film was evaluated using a contact chain. Specifically, a contact resistance measuring pattern including 50 contact holes continuously formed therein was formed. Thus, the contact resistance converted per contact hole was calculated. In Tables 2, 3, and 4, the contact resistance relative evaluation column is provided, and evaluation was made based on the following criteria. In this example and examples described later, in any case, a sample with a contact resistance of 1.0×10³Ω or less (A in relative evaluation) is judged as acceptable.
A: 1.0×10³Ω or less
B: more than 1.0×10³Ω and 1.0×10⁴Ω or less
C: more than 1.0×10⁴Ω or less

These results are shown in Tables 2 and 3 below. Table 2 shows the results of the first Al alloy films, and Table 3 shows the results of the second Al alloy films.

TABLE 2

| | | pH = 7 | | | pH = 8 | | | pH = 9 | | | pH = 9.5 | | |
|---|---|---|---|---|---|---|---|---|---|---|---|---|---|
| | | | Contact | | | Contact | | | Contact | | | Contact | |
| | | Ra | resistance | | Ra | resistance | | Ra | resistance | | Ra | resistance | |
| | | (nm) | (Ω) | | (nm) | (Ω) | | (nm) | (Ω) | | (nm) | (Ω) | |
| Immersion | 0 | 1.1 | 7.3E+06 | C | 1.1 | 7.3E+06 | C | 1.1 | 7.3E+06 | C | 1.1 | 7.3E+06 | C |
| time | 20 | 1.2 | 5.7E+06 | C | 1.2 | 8.0E+06 | C | 1.1 | 2.1E+07 | C | 1.1 | 1.8E+06 | C |
| (sec) | 40 | — | — | — | — | — | — | 1.1 | 3.5E+05 | C | 1.6 | 2.0E+03 | B |
| | 60 | 1.1 | 7.1E+06 | C | 1.0 | 6.8E+06 | C | 1.3 | 4.1E+06 | C | 1.9 | 3.2E+03 | B |
| | 120 | — | — | — | — | — | — | 1.6 | 1.3E+05 | C | 2.8 | 7.6E+02 | A |
| | 300 | — | — | — | — | — | — | — | — | — | 6.9 | 7.2E+02 | A |
| | 600 | — | — | — | — | — | — | — | — | — | 19.8 | 6.5E+02 | A |
| | 900 | 1.2 | 6.1E+06 | C | 1.3 | 4.6E+06 | C | — | — | — | 56.5 | 1.0E+09 | C |

| | | pH = 10 | | | pH = 10.5 | | | pH = 11 | | |
|---|---|---|---|---|---|---|---|---|---|---|
| | | | Contact | | | Contact | | | Contact | |
| | | Ra | resistance | | Ra | resistance | | Ra | resistance | |
| | | (nm) | (Ω) | | (nm) | (Ω) | | (nm) | (Ω) | |
| Immersion | 0 | 1.1 | 7.3E+06 | C | 1.1 | 7.3E+06 | C | 1.1 | 7.3E+06 | C |
| time | 20 | 1.6 | 1.8E+05 | C | 1.7 | 6.8E+04 | C | — | — | — |
| (sec) | 40 | 2.2 | 5.4E+02 | A | 2.1 | 1.6E+03 | B | 2.1 | 3.0E+03 | B |
| | 60 | 3.0 | 7.6E+02 | A | 2.5 | 2.5E+02 | A | 2.5 | 9.9E+02 | A |
| | 120 | 3.5 | 9.3E+02 | A | 3.2 | 4.7E+02 | A | 5.6 | 5.7E+02 | A |
| | 300 | 28.9 | 2.8E+08 | C | — | — | — | 30.5 | 2.8E+06 | C |
| | 600 | — | — | — | — | — | — | — | — | — |
| | 900 | — | — | — | — | — | — | — | — | — |

(Note)
In the table, “E+0X (X: integer)” means “10^{x}”.

TABLE 3

| | | pH = 7 | | | pH = 8 | | | pH = 9 | | | pH = 9.5 | | |
|---|---|---|---|---|---|---|---|---|---|---|---|---|---|
| | | | Contact | | | Contact | | | Contact | | | Contact | |
| | | Ra | resistance | | Ra | resistance | | Ra | resistance | | Ra | resistance | |
| | | (nm) | (Ω) | | (nm) | (Ω) | | (nm) | (Ω) | | (nm) | (Ω) | |
| Immersion | 0 | 1.0 | 6.0E+08 | C | 1.0 | 6.0E+08 | C | 1.0 | 6.0E+08 | C | 1.0 | 6.0E+08 | C |
| time | 20 | 1.3 | 5.1E+08 | C | 1.2 | 3.3E+06 | C | 1.3 | 1.1E+06 | C | 1.6 | 8.0E+03 | B |
| (sec) | 40 | 1.2 | 4.7E+08 | C | 1.3 | 3.7E+04 | C | 1.4 | 1.6E+04 | C | 2.0 | 2.3E+03 | B |
| | 60 | 1.2 | 3.7E+08 | C | 1.6 | 9.2E+03 | B | 1.6 | 4.1E+03 | B | 2.4 | 8.7E+02 | A |
| | 120 | — | — | — | 1.7 | 5.1E+03 | B | 1.9 | 1.4E+03 | B | 2.9 | 5.9E+02 | A |
| | 300 | — | — | — | 2.0 | 1.3E+03 | B | 2.2 | 5.6E+02 | A | 8.1 | 2.1E+02 | A |
| | 600 | — | — | — | 2.4 | 6.6E+02 | A | 2.4 | 4.9E+02 | A | — | — | — |
| | 900 | 1.4 | 4.5E+08 | C | 2.5 | 3.9E+02 | A | — | — | — | — | — | — |

| | | pH = 10 | | | pH = 10.5 | | | pH = 11 | | |
|---|---|---|---|---|---|---|---|---|---|---|
| | | | Contact | | | Contact | | | Contact | |
| | | Ra | resistance | | Ra | resistance | | Ra | resistance | |
| | | (nm) | (Ω) | | (nm) | (Ω) | | (nm) | (Ω) | |
| Immersion | 0 | 1.0 | 6.0E+08 | C | 1.0 | 6.0E+08 | C | 1.0 | 6.0E+08 | C |
| time | 20 | 1.5 | 6.6E+03 | B | 2.5 | 2.6E+02 | A | 2.5 | 2.1E+02 | A |
| (sec) | 40 | 2.7 | 7.9E+02 | A | 2.8 | 2.0E+02 | A | 3.1 | 1.7E+02 | A |
| | 60 | 3.6 | 4.8E+02 | A | 3.7 | 1.8E+02 | A | 4.1 | 1.4E+02 | A |
| | 120 | 8.7 | 2.5E+02 | A | 11.3 | 1.1E+02 | A | 14.1 | 9.5E+01 | A |
| | 300 | 30.2 | 3.3E+08 | C | — | — | — | 38.1 | 7.4E+05 | C |
| | 600 | — | — | — | — | — | — | — | — | — |
| | 900 | — | — | — | — | — | — | — | — | — |

(Note)
In the table, “E+0X (X: integer)” means “10^{x}”.

As apparent from the results shown in Tables 2 and 3, by adjusting the pH and immersion time of the alkali aqueous solution, and adjusting the arithmetic mean roughness Ra of the surface of the Al alloy film to 2.2 to 20 nm, it is possible to reduce the contact resistance between the Al alloy film and the ITO film.

### Example 2-2

In this example, the effect of the alkali solution for use in control of Ra exerted on the contact resistance was studied.

First, with the same DC magnetron sputtering and heat treatment as in Example 2-1, an Al-0.6 at % Ni-0.5 at % Cu—0.3 at % La alloy film was deposited to form intermetallic compounds. The Al alloy film was immersed in an alkali aqueous solution of amines shown in Table 4 below for 60 seconds, and was washed with water/dried. Thus, in the same manner as in Example 2-1, the arithmetic mean roughness Ra was measured. Incidentally, the concentration of amines in the alkali aqueous solution is 5.5×10⁻⁴ vol %.

In the same manner as in Example 2-1, an ITO film was deposited on the surface of each Al alloy film measured for Ra, and the contact resistance thereof was measured. The results are shown in Table 4 below.

TABLE 4

| Alkali aqueous solution | | Ra | Contact resistance | |
|---|---|---|---|---|
| Amine species | | (nm) | (Ω) | |
| Monoethanolamine | Alkanolamine | 2.5 | 2.5E+02 | A |
| Diethanolamine | Alkanolamine | 2.8 | 5.3E+02 | A |
| Phenylalanine | Aromatic amine | 1.1 | 6.2E+06 | C |
| Tyrosine | Aromatic amine | 1.4 | 8.2E+06 | C |
| o-aminobenzoic acid | Aromatic amine | 1.3 | 2.8E+06 | C |
| 2-aminopyridine | Aromatic amine | 1.1 | 7.4E+06 | C |
| 1-naphthylamine | Aromatic amine | 1.3 | 7.1E+06 | C |

(Note) In the table, “E+0X (X: integer)” means “10^{X}”.

The results shown in Table 4 indicates that, when the addition amount of the X1 element is low (less than 1%), amines used for the alkali aqueous solution are preferably alkanolamines (particularly, ethanolamines).

### Example 2-3

In this example, the effect of the composition of the Al alloy film exerted on the contact resistance or the like was studied.

First, a non-alkali glass plate (gage: 0.7 mm) was used as a substrate. On the surface, each Al alloy film having its corresponding composition shown in Table 5 below was deposited by DC magnetron sputtering at room temperature (film thickness 300 nm).

In the same manner as in Example 2-1, intermetallic compounds of the Al alloy films were formed, and the sizes (maximum diameters) were measured. The results are shown in Table 5 below.

Then, each Al alloy film after the heat treatment was immersed in an alkali aqueous solution obtained by diluting an alkali solution of 60 vol % of monoethanolamine and 40 vol % of DMSO with water, and adjusting the pH to 9.5 for 300 seconds. Then, 1-minute washing with pure water/nitrogen blow drying were performed. The arithmetic mean roughness Ra of the Al alloy film surface was measured in the same manner as in Example 2-1. The results are shown in Table 5 below.

In the same manner as in Example 2-1, an ITO film was deposited on the surface of each Al alloy film measured for Ra, and the contact resistance was measured. The results are shown in Table 5 below.

Separately from each Al alloy film measured for the intermetallic compound sizes, Ra, and the contact resistance, another Al alloy film with the same composition was manufactured. The Al alloy film was immersed in an alkali aqueous solution obtained by diluting an alkali solution of 60 vol % of monoethanoamine and 40 vol % of DMSO with water, and adjusting the pH to 10 for 300 seconds, followed by water washing/drying. The crater corrosions (black spots) of the Al alloy film were measured by an optical microscope (observation magnification 1000 times, observation area: 10 μm×10 μm). Thus, the density thereof was measured. During observation, when a contrast is caused definitely, and is recognized as a black spot, this is judged as a defect. In this example, a sample in which the crater corrosion density is roughly 5 marks/100 μm² or less was judged as acceptable (excellent in corrosion resistance). The results are shown in Table 5 below.

TABLE 5

| | | | | Characteristics | | | |
|---|---|---|---|---|---|---|---|
| | Alloy | | | | Intermetallic | Contact | Crater |
| | composition | | | Ra | compound size | resistance | corrosion |
| No | Ni | Ge | La | (nm) | (nm) | (Ω) | (marks/100 μm²) |
| 1 | 0.5 | 0.5 | 0.3 | 3.1 | 50-140 | 660 | 1 |
| 2 | 0.5 | 1 | 0.3 | 3.3 | 50-125 | 500 | 1 |
| 3 | 0.5 | 2 | 0.3 | 3.4 | 50-120 | 350 | 1 |
| 4 | 1 | 0.5 | 0.3 | 5.7 | 60-130 | 190 | 3 |
| 5 | 2 | 0.5 | 0.3 | 12.1 | 60-150 | 60 | 11 |
| 6 | 4 | 0.5 | 0.3 | 24.1 | 120-230 | 50 | 20 |
| 7 | 8 | 0.5 | 0.3 | 38.7 | 150-300 | 50 | 42 |
| 8 | 1 | 0.5 | 0.2 | 9.1 | 80-130 | 120 | 4 |
| 9 | 1 | 0.5 | 0.1 | 11.7 | 80-150 | 120 | 3 |
| 10 | 1 | 0.5 | — | 31.5 | 100-350 | 160 | 20 |
| 11 | 1 | 1 | — | 39.2 | 100-350 | 190 | 23 |
| 12 | 0.5 | 2 | — | 27.1 | 60-300 | 300 | 12 |

(Notes)
Unit of alloy composition: at %. Balance of alloy: Al and inevitable impurities

First, Nos. 1 to 5, 8, and 9 are examples in all of which the composition of the Al alloy film satisfies the preferred requirements of the present invention. The Ra and the intermetallic compound size were also properly controlled, and hence both reduction of the contact resistance and the corrosion resistance were excellent.

In contrast, Nos. 6 and 7 are examples in which the Ni content exceeds the preferred range of the present invention. The contact resistance was favorable, but the intermetallic compounds became coarse, resulting in deterioration of the corrosion resistance.

### Example 3-1

The Al alloy films (film thickness=300 nm) with various alloy compositions shown in Table 6 were deposited with a DC magnetron sputtering process (substrate=glass substrate (Eagle 2000 manufactured by Corning Co.), atmosphere gas=argon, pressure=2 mTorr, substrate temperature=25° C. (room temperature).

Incidentally, for formation of the Al alloy films with the various alloy compositions, Al alloy targets with various compositions manufactured by a vacuum dissolution process were used as sputtering targets.

Further, the content of each alloy element in various Al alloy films used in Examples was determined with an ICP spectrometry (inductively coupled plasma spectrometry) process.

Using each Al alloy film deposited in the foregoing manner, the electric resistivity of the Al alloy film itself after the heat treatment, the direct contact resistance (contact resistance with ITO) when the Al alloy film is directly connected to the transparent pixel electrode, the alkali developing solution resistance and the peeling liquid resistance as the corrosion resistances, and the heat resistance were measured with the following methods, respectively. These results are also shown in Table 6.

(1) Electric resistivity of Al alloy film itself after heat treatment

For the Al alloy film, a 10-μm width line-and-space pattern was formed. Thus, in an inert gas atmosphere, a 15-minute heat treatment at 270° C. was performed. Then, the electric resistivity was measured with a four-terminal method. Then, the quality of the electric resistance of the Al alloy film itself after the heat treatment was judged according to the following criteria.

### (Evaluation Criteria)

A: 4.5 μΩ·cm or less)
B: more than 4.5 μΩ·cm and less than 5.0 μΩ·cm
C, 5.0 μΩ·cm or more

(2) Direct contact resistance with transparent pixel electrode

For the contact resistance when the Al alloy film and the transparent pixel electrode were in direct contact with each other, the transparent pixel electrode (ITO; indium tin oxide obtained by adding 10 mass % tin oxide to indium oxide) was sputtered under the following conditions. As a result, a Kelvin pattern (contact hole size: 10 μm square) shown in FIG. 25 was manufactured, and the four-terminal measurement (a method in which an electric current is caused to flow through the ITO-Al alloy film, and at another terminal, the voltage drop across the ITO-Al alloy is measured) was performed. Specifically, a current I is caused to flow across I₁—I₂ of FIG. 25, and the voltage V across V₁—V₂ was monitored, thereby to determine the direct contact resistance R of the contact part C as [R=(V₁−V₂)/I₂]. Then, the quality of the direct contact resistance with ITO was judged according to the following criteria.

### (Transparent Pixel Electrode Deposition Conditions)

Atmosphere gas=Argon
Pressure=0.8 mTorr
Substrate temperature=25° C. (room temperature)

### (Evaluation Criteria)

A: less than 1000 Ω;
B: 1000Ω or more

(3) Alkali developing solution resistance (measurement of developing solution etching rate)

The Al alloy film deposited on the substrate was masked, and then was immersed in a developing solution (aqueous solution containing 2.38 mass % TMAH) at 25° C. for 1 minute. The etching amount was measured by means of a stylus profilometer. Then, the quality of the alkali developing solution resistance was judged according to the following criteria.

### (Evaluation Criteria)

A: less than 60 nm/min
B: 60 nm or more and 100 nm or less/min
C: more than 100 nm/min

(4) Peeling liquid resistance

Simulating the washing step of the photoresist peeling liquid, there was performed a corrosion experiment with an alkaline aqueous solution of a mixture of an amine-based photoresist and water. Particularly, an amine-based resist peeling liquid “TOK106” aqueous solution manufactured by TOKYO OHKA KOGYO Co., Ltd., adjusted to a pH of 10 (liquid temperature 25° C.) was prepared. Therein, a film obtained by heat-treating the Al alloy film in an inert gas atmosphere at 330° C. for 30 minutes was immersed for 300 seconds. Then, the number of crater-like corrosion (pitting corrosion) marks (with a circle-equivalent diameter of 150 nm or more) observed in the film surface after immersion was checked (observation magnification 1000 times). Then, the quality of the peeling liquid resistance was judged according to the following criteria.

### (Evaluation Criteria)

A: less than 10 marks/100 μm²
B: 10 marks or more and 20 marks or less/100 μm²
C: more than 20 marks/100 μm²

(5) Heat resistance

The Al alloy film deposited on the substrate was heat-treated in a nitrogen gas atmosphere at 350° C. for 30 minutes. Then, the surface conditions were observed by means of an optical microscope (magnification: 500 times), and the presence or absence of hillocks was visually observed. Then, the heat resistance was evaluated according to the following criteria.

### (Evaluation Criteria)

A: No hillock and no surface roughness
B: No hillock but surface roughness observed
C: Hillocks observed

Further, for the “150 nm or more intermetallic compound density” in Table 6, a sample with the value of less than one compound/100 μm² is indicated with A; and a sample of one compound/100 μm² or more, as B.

Whereas, for the evaluation of the “X1—X2 and Al—X1—X2 to total ratio of 50% or more” in Table 6, a sample in which the total area of the intermetallic compounds of X1—X2 and Al—X1—X2 is 50% or more of the total area of all the intermetallic compounds is indicated with A; and a sample of less than 50%, as B.

TABLE 6

| | | Electric resistivity | | | | | |
|---|---|---|---|---|---|---|---|
| | | after 270° C. | | | | Developing solution | |
| | | heat treatment | | Crater corrosion | | etching rate | |
| No. | Composition* | (μΩ · cm) | | density (marks/100 μm²) | | (nm/min.) | |
| 1 | Al—0.5Ni—0.3La | 3.9 | A | 14.6 | B | 26 | A |
| 2 | Al—0.5Ni—0.2Ge—0.3La | 4.0 | A | 11.0 | B | 34 | A |
| 3 | Al—0.5Ni—0.5Ge—0.3La | 4.0 | A | 0.4 | A | 42 | A |
| 4 | Al—0.5Ni—1.0Ge—0.3La | 4.3 | A | 0.8 | A | 46 | A |
| 5 | Al—0.5Ni—1.5Ge—0.1La | 5.0 | C | 5.3 | A | 55 | A |
| 6 | Al—0.5Ni—2.0Ge—0.1La | 5.3 | C | 22.0 | C | 69 | B |
| 7 | Al—0.2Ni—1.5Ge—0.1La | 4.8 | B | 2.5 | A | 40 | A |
| 8 | Al—0.2Ni—0.5Ge—0.1La | 3.9 | A | 0.4 | A | 35 | A |
| 9 | Al—0.5Ni—0.5Ge—0.3Nd | 3.9 | A | 0.4 | A | 43 | A |
| 10 | Al—0.5Ni—0.5Ge—0.3Gd | 4.2 | A | 0.6 | A | 40 | A |
| 11 | Al—0.4Ni—0.2Co—0.2Ge—0.1La | 3.8 | A | 0.6 | A | 31 | A |
| 12 | Al—0.4Ni—0.2Co—0.5Ge—0.1La | 4.1 | A | 0.4 | A | 35 | A |
| 13 | Al—0.4Ni—0.2Co—1.0Ge—0.1La | 4.5 | A | 0.6 | A | 43 | A |
| 14 | Al—0.4Ni—0.5Co—1.0Ge—0.1La | 5.0 | C | 3.5 | A | 58 | A |
| 15 | Al—0.5Ni—0.5Mg—0.2Ge—0.3La | 4.2 | A | 2.0 | A | 36 | A |
| 16 | Al—0.5Ni—0.5Zn—0.3La | 4.3 | A | 51.0 | C | 75 | B |
| 17 | Al—0.5Ni—0.5In—0.3La | 4.5 | A | 76.3 | C | 122 | C |
| 18 | Al—0.5Ni—0.5B—0.3La | 4.5 | A | 45.3 | C | 64 | B |
| 19 | Al—1.5Ge—0.3La | 4.8 | B | 1.6 | A | 30 | A |
| 20 | Al—1.0Ni—0.5Ge—0.3La | 4.5 | A | 23.0 | C | 106 | C |
| 21 | Al—1.0Ni—0.2Ge—0.3La | 4.3 | A | 12.0 | B | 101 | C |
| 22 | Al—0.5Ni—0.5Ge—0.3Y | 4.2 | A | 6.0 | A | 44 | A |
| 23 | Al—0.5Ni—0.5Ge—0.3Ce | 4.4 | A | 3.3 | A | 43 | A |
| 24 | Al—0.5Ni—0.5Ge—0.3Pr | 4.2 | A | 4.0 | A | 42 | A |
| 25 | Al—0.5Ni—0.5Ge—0.3Dy | 4.5 | A | 6.4 | A | 42 | A |
| 26 | Al—0.2Ni—0.5Ge | 4.0 | A | 50 | C | 65 | B |

| | Contact | | Heat | 150-nm or more | X1-X2 and Al-X1-X2 |
|---|---|---|---|---|---|
| | resistance | | resistance | intermetallic | to total ratio of |
| No. | with ITO (Ω) | | (350° C.) | compound density | 50% or more |
| 1 | 100200 | B | A | — | — |
| 2 | 652800 | B | A | A | A |
| 3 | 372 | A | A | A | A |
| 4 | 970 | A | A | A | A |
| 5 | 1060 | B | A | A | A |
| 6 | 5260 | B | A | B | A |
| 7 | 912 | A | A | A | A |
| 8 | 240 | A | A | A | A |
| 9 | 406 | A | A | A | A |
| 10 | 350 | A | A | A | A |
| 11 | 36655 | B | A | A | A |
| 12 | 154 | A | A | A | A |
| 13 | 163 | A | A | A | A |
| 14 | 200 | A | A | A | A |
| 15 | 2720 | B | A | A | A |
| 16 | 1687500 | B | A | B | A |
| 17 | 5892500 | B | A | B | A |
| 18 | 636900 | B | A | B | A |
| 19 | 1256 | B | A | — | — |
| 20 | 160 | A | A | B | A |
| 21 | 420 | A | A | A | A |
| 22 | 554 | A | A | A | A |
| 23 | 589 | A | A | A | A |
| 24 | 856 | A | A | A | A |
| 25 | 963 | A | A | A | A |
| 26 | 578 | A | C | B | B |

*The numerical value denotes percentage in at % of the Al alloy film.

The results shown in Table 6 indicate the following. First, an Al alloy film including prescribed amounts of Ni, Ge, and rare earth elements is implemented. As a result, even a heat treatment at low temperatures can sufficiently reduce the electric resistance, and can largely reduce the direct contact resistance with ITO (transparent pixel electrode), namely can achieve a low contact resistance. Further, the Al alloy film is also excellent in corrosion resistance and heat resistance.

Further, an Al alloy film including Co is implemented. As a result, the contact resistance can be more reduced, and the corrosion resistance (particularly, alkali developing solution resistance) can be more enhanced.

In contrast, when Ni is not included therein, a low contact resistance cannot be achieved. On the other hand, when the Ni content exceeds the upper limit, the sample is inferior in corrosion resistances (alkali developing solution resistance, peeling liquid resistance).

For the Al alloy film not including Ge or having an insufficient Ge content, the contact resistance cannot be sufficiently reduced.

Whereas, when Zn, In, or B is included therein in place of Ge, a sample excellent in corrosion resistance cannot be obtained. On the other hand, when Ge is excessive, the electric resistance cannot be reduced sufficiently after a heat treatment at low temperatures, and the sample is inferior in corrosion resistance.

For a sample in which each element content is within the prescribed range, but the total content of Ni+Ge, or the total content of Ni+Ge+Co exceeds the upper limit, the electric resistance cannot be sufficiently reduced after the heat treatment at low temperatures.

Further, a sample not including a rare earth element cannot ensure the corrosion resistance and the heat resistance.

The present invention was described in details by reference to specific embodiments. However, it is apparent to those skilled in the art that various changes and modifications may be made without departing from the spirit and scope of the present invention.

The present application is based on Japanese Patent application (Japanese Patent Application No. 2008-093992) filed on Mar. 31, 2008, Japanese Patent application (Japanese Patent Application No. 2008-114333) filed on Apr. 24, 2008, and Japanese Patent application (Japanese Patent Application No. 2008-296005) filed on Nov. 19, 2008 the entire contents of which are hereby incorporated by reference.

### INDUSTRIAL APPLICABILITY

In accordance with the present invention, it is possible to provide a display device including an aluminum alloy film which has acquired a low electric resistivity and a low contact resistance with a transparent electroconductive film even after undergoing a low-temperature heat treatment (300° C. or less) in a direct contact material, and has been improved in corrosion resistance and heat resistance of the Al alloy by control of additional elements and intermetallic compounds.

Further, by allowing the Al alloy film to include an element X2, the intermetallic compounds (precipitates) become finer, and the corrosion resistance is improved, which can prevent crater corrosion. Whereas, by controlling the arithmetic mean roughness Ra of the Al alloy film surface within a proper range, the contact resistance can be reduced.

Further, it is possible to provide an Al alloy film for a display device, which is configured such that the Al alloy film can be directly connected to the transparent pixel electrode (transparent electroconductive film, oxide electroconductive film) without a barrier metal layer interposed therebetween, and which exhibits a sufficiently low electric resistance even when applied with a relatively low heat treatment temperature (e.g., 250 to 300° C.), and is excellent in corrosion resistances (alkali developing solution resistance, peeling liquid resistance), and further is also excellent in heat resistance. Incidentally, the heat treatment temperature denotes the treatment temperature which is the highest temperature during the production steps (e.g., a production step of a TFT substrate) of the display device. In the production steps of a general display device, the heat treatment temperature means the heating temperature of the substrate during CVD deposition for formation of various thin films, the temperature of a heat treatment furnace for heat setting the protective film, or the like.

Whereas, when the Al alloy film of the present invention is applied to a display device, the barrier metal layer can be omitted. Therefore, use of the Al alloy film of the present invention can provide a display device excellent in productivity, low in cost, and high in performance.

1. A display device, comprising: an oxide electroconductive film and an Al alloy film being in direct contact with each other, at least a part of Al alloy components being precipitated and present on the contact surface of the Al alloy film,
wherein the Al alloy film comprises at least one element X1 selected from the group consisting of Ni, Ag, Zn, and Co, and at least one element X2 capable of forming an intermetallic compound with the element X1, wherein the intermetallic compound represented by at least one of X1—X2 and Al—X1—X2 with a maximum diameter of 150 nm or less is formed.

2. The display device according to claim 1, wherein the density of the intermetallic compound represented by at least one of X1—X2 and Al—X1—X2 with a maximum diameter of 150 nm or more is less than one compound/100 μm².

3. The display device according to claim 1, wherein at least a part of the element X2 is precipitated into the Al matrix by a 300° C. or less heat treatment.

4. The display device according to claim 3, wherein at least a part of the element X2 is precipitated into the Al matrix by a 150° C. or more and 230° C. or less heat treatment.

5. The display device according to claim 4, wherein at least a part of the element X2 is precipitated into the Al matrix by a 200° C. or less heat treatment.

6. The display device according to claim 1, wherein the total area of the intermetallic compounds of X1—X2 and Al—X1—X2 in the Al alloy film is 50% or more of the total area of all the intermetallic compounds.

7. The display device according to claim 1, wherein in the Al alloy film, the element X1 is Ni, and the element X2 is Ge or Cu, or mixtures thereof, and at least one intermetallic compound of Al—Ni—Ge and Al—Ni—Cu is formed with a 300° C. or less heat treatment.

8. The display device according to claim 1, wherein the arithmetic mean roughness Ra of the contact surface of the Al alloy film is 2.2 nm or more and 20 nm or less.

9. The display device according to claim 8, wherein the Al alloy film comprises the element X1 in a total amount of from 0.05 to 2 at %.

10. The display device according to claim 9, wherein the element X2 is at least one of Cu and Ge, and the Al alloy film comprises at least one of the Cu and Ge in a total amount of from 0.1 to 2 at %.

11. The display device according to claim 9, wherein the Al alloy film further comprises at least one of rare earth elements in a total amount of from 0.05 to 0.5 at %.

12. The display device according to claim 11, wherein the rare earth element is at least one element selected from the group consisting of La, Nd, and Gd.

13. A process for producing the display device according to claim 8, comprising:
bringing the Al alloy film into contact with an alkali solution before bringing the Al alloy film into direct contact with the oxide electroconductive film, and adjusting the arithmetic mean roughness Ra of the surface of the Al alloy film to 2.2 nm or more and 20 nm or less.

14. The production process according to claim 13, wherein the alkali solution is an aqueous solution comprising ammonia or alkanolamines.

15. The production process according to claim 13, wherein adjustment of the arithmetic mean roughness Ra is performed in the peeling step of a resist film.

16. The display device according to claim 1, wherein the Al alloy film comprises Ni in an amount of from 0.05 to 0.5 at % as the element X1, and Ge in an amount of from 0.4 to 1.5 at % as the element X2, and further comprises at least one element selected from the group of rare earth elements in a total amount of from 0.05 to 0.3 at %, and wherein the total content of Ni and Ge is from 1.7 at % or less.

17. The display device according to claim 16, wherein the group of rare earth elements comprises Nd, Gd, La, Y, Ce, Pr, and Dy.

18. The display device according to claim 16, wherein Co is further comprised in an amount of 0.05 to 0.4 at % as the X1 element, and the total content of Ni, Ge, and Co is 1.7 at % or less.

19. A sputtering target comprising Ni in an amount of 0.05 to 0.5 at %, Ge in an amount of 0.4 to 1.5 at %, and at least one element selected from the group of rare earth elements in a total amount of 0.05 to 0.3 at %, the total content of Ni, and Ge being 1.7 at % or less, and the balance being Al and inevitable impurities.

20. The sputtering target according to claim 19, wherein the group of rare earth elements comprises Nd, Gd, La, Y, Ce, Pr, and Dy.

21. The sputtering target according to claim 19, further comprising Co in an amount of from 0.05 to 0.4 at %, and wherein the total content of Ni, Ge, and Co is 1.7 at % or less.
